(19) United States
(12) Patent Application Publication
(10) Pub. No.: US 2025/0338709 A1
(43) Pub. Date: Oct. 30, 2025

(54) SEMICONDUCTOR NANOPARTICLE, PRODUCTION METHOD THEREOF, AND ELECTRONIC DEVICE INCLUDING THE SAME

(71) Applicant: SAMSUNG ELECTRONICS CO., LTD., Suwon-si (KR)

(72) Inventors: Jun Ho LEE, Suwon-si (KR); Sung Woo KIM, Suwon-si (KR); Hogeun CHANG, Suwon-si (KR); Kwang Hee KIM, Suwon-si (KR); Sungi KIM, Suwon-si (KR)

(21) Appl. No.: 19/193,512

(22) Filed: Apr. 29, 2025

(30) Foreign Application Priority Data
Apr. 29, 2024 (KR) 10-2024-0056947
Aug. 27, 2024 (KR) 10-2024-0115306

(51) Int. Cl. H10K 50/115; B82Y 20/00; B82Y 40/00; C09K 11/56; C09K 11/88; H10K 59/10

(52) U.S. Cl. CPC H10K 50/115; C09K 11/565; C09K 11/883; B82Y 20/00; B82Y 40/00; H10K 59/10

(57) ABSTRACT

A semiconductor nanoparticle, a method for producing the semiconductor nanoparticle, and an electronic device including the semiconductor nanoparticle. The semiconductor nanoparticle includes a template crystal including a zinc chalcogenide and is cadmium-free. The template crystal includes zinc-chalcogen bilayers stacked in a [111] direction. In high-resolution scanning transmission electron microscopy analysis, the template crystal includes a first zone, a second zone, and a mirror zone disposed between the first zone and the second zone. The mirror zone includes at least one mirror plane where a reversal occurs in the atomic arrangement direction of zinc and chalcogen elements between adjacent zinc-chalcogen bilayers. In the zinc-chalcogen bilayers of the first zone, zinc atoms and chalcogen element atoms are arranged in a first direction. In the zinc-chalcogen bilayers of the second zone, zinc atoms and chalcogen element atoms are arranged in a second direction.

### CROSS-REFERENCE TO RELATED APPLICATION

This application is based on and claims priority to Korean Patent Applications Nos. 10-2024-0056947 and 10-2024-0115306, filed in the Korean Intellectual Property Office, on Apr. 29 and Aug. 27, 2024, respectively, and all the benefits accruing therefrom under 35 U.S.C. § 119, the contents of which are herein incorporated by reference in their entirety.

### BACKGROUND

### 1. Field

The present disclosure relates to a semiconductor nanoparticle, a method for manufacturing the semiconductor nanoparticle, and an electroluminescent device including the semiconductor nanoparticle.

### 2. Description of the Related Art

A semiconductor nanoparticle (e.g., a quantum dot) having a nanoscale size may exhibit a luminescent property. For example, a quantum dot including a semiconductor nanocrystal may exhibit a quantum confinement effect. Light emission of the semiconductor nanoparticle may be generated when electrons in an excited state transition from a conduction band to a valence band by, for example, light excitation or voltage application. The semiconductor nanoparticle may be configured to emit light in a desired wavelength region by controlling a size thereof, a composition thereof, or a combination thereof. The semiconductor nanoparticle may be used in various light emitting devices (e.g., electroluminescent devices) and display devices.

### SUMMARY

An embodiment relates to a semiconductor nanoparticle or a population thereof.

An embodiment relates to a method of producing, e.g., a method of manufacturing, the semiconductor nanoparticle.

An embodiment relates to a light emitting device that emit light by themselves when voltage is applied to the aforementioned semiconductor nanoparticle (e.g., the quantum dot).

An embodiment relates to a display device (e.g., a quantum dot (QD)-light emitting diode (LED) display) comprising nanocrystal particles (e.g., quantum dots) as a light emitting material in red/green/blue pixels.

In an embodiment, a semiconductor nanoparticle includes a template crystal including a zinc chalcogenide and does not include cadmium, wherein the template crystal includes zinc-chalcogen element bilayers (hereinafter, can be referred to as zinc-chalcogen bilayers) stacked in a [111] direction, and as determined using a (high-resolution) scanning transmission electron microscope, the template crystal includes a first zone, a second zone, and a mirror zone disposed between the first zone and the second zone,
wherein the mirror zone includes a (e.g., at least one) mirror plane where a reversal (e.g., reflection) occurs in an atomic arrangement direction of zinc and a chalcogen element between adjacent layers of the zinc-chalcogen bilayers,
wherein in the zinc-chalcogen bilayers of the first zone, zinc atoms and chalcogen element atoms are arranged in a first direction, and in the zinc-chalcogen bilayers of the second zone, zinc atoms and chalcogen element atoms are arranged in a second direction,
wherein the first direction is symmetric, e.g., substantially symmetric, for example, substantially reflection symmetric, or substantially identical (e.g., parallel or substantially parallel) to the second direction,
wherein in at least a portion of the first zone, lengths of the zinc-chalcogen bilayers decrease as being away from the mirror zone, and in at least a portion of the second zone, lengths of the zinc-chalcogen bilayers decrease as being away from the mirror zone, and
wherein the mirror zone has a thickness of less than or equal to about 50% of a total height of the template crystal.

The zinc chalcogenide may include zinc and selenium. The chalcogen element may include (e.g., may be) selenium and optionally tellurium. The zinc chalcogenide may further include tellurium. The template crystal may include a first zinc chalcogenide including zinc, selenium, and tellurium; a second zinc chalcogenide including zinc and selenium and not including tellurium; or a combination thereof.

In the mirror zone, a number of the mirror planes may be greater than or equal to about 1 and less than or equal to about 10.

The mirror zone includes an odd number (e.g., 1, 3, 5, 7, or 9) of mirror planes, and the first direction and the second direction may be substantially symmetric (e.g., symmetric) to each other.

The mirror zone includes an even number (e.g., 2, 4, 6, 8, or 10) of mirror planes, and the first direction and the second direction may be substantially parallel (e.g., parallel) to each other.

The template crystal may include at least four, for example, at least six or at least eight, (100) crystal facets.

In the first zone, a d-spacing between adjacent the zinc-chalcogen bilayers in the <111> direction may be greater than or equal to about 1 angstrom (Å), or greater than or equal to about 3 Å and less than or equal to about 4 Å. In the second zone, a d-spacing between adjacent zinc-chalcogen bilayers in the <111> direction may be greater than or equal to about 1 Å, greater than or equal to about 3 Å, greater than or equal to about 3.2 Å, and less than or equal to about 4 Å.

Each of the first zone and the second zone may independently have a shape of a pyramid. The pyramid may be a trigonal pyramid. The pyramid may be a right triangular pyramid. The shape of the pyramid may have at least one truncated edge, for example, at least two or at least three truncated edges.

The mirror zone may include a first surface (e.g., a top mirror plane) facing the first zone and a second surface (e.g., a base mirror plane) opposite to the first surface. The first zone may be disposed on (or directly on) the first surface. The second zone may be disposed on (or directly on) the second surface.

The mirror zone may have a shape of a prism or an antiprism, for example with two, for example identical, polygonal bases (e.g., triangular bases). The mirror zone may have a shape of a prism (e.g., a triangular prism) or an antiprism, wherein the first surface and the second surface correspond to the first and second bases of the prism or the antiprism. The mirror zone may have a shape of a triangular prism or a triangular antiprism.

The template crystal may have a trigonal bipyramidal shape. The template crystal may have a cube-like bipyramidal shape. The template crystal may have an elongated bipyramidal shape. The template crystal may have a gyroelongated bipyramidal shape.

A total height of the template crystal may be greater than or equal to about 5 nanometers (nm), or greater than or equal to about 7 nm. The total height of the template crystal may be less than or equal to about 50 nm, less than or equal to about 45 nm, or less than or equal to about 40 nm.

In the first zone, a number of zinc-chalcogen bilayers may be greater than or equal to about 3, or greater than or equal to about 5 and less than or equal to about 20, or less than or equal to about 10. In the second zone, a number of zinc-chalcogen bilayers may be greater than or equal to about 3, or greater than or equal to about 5 and less than or equal to about 20, or less than or equal to about 10.

The mirror region may include (e.g., consist of) a single mirror surface. The mirror region may have a thickness greater than or equal to about 0.2 nm, greater than or equal to about 0.3 nm, greater than or equal to about 0.5 nm, and less than or equal to about 10 nm, or less than or equal to about 7 nm. A length of the mirror region may be greater than or equal to about 3 nm, greater than or equal to about 5 nm, or greater than or equal to about 8 nm, and less than or equal to about 80 nm, less than or equal to about 60 nm, or less than or equal to about 40 nm.

The first zinc chalcogenide or the template crystal may further include tellurium. In the template crystal, a mole ratio of selenium to zinc may be greater than or equal to about 0.5:1, greater than or equal to about 0.7:1, greater than or equal to about 1:1, and less than or equal to about 1.5:1, less than or equal to about 1.2:1, or less than or equal to about 1:1. In the template crystal, a mole ratio of sulfur to zinc may be greater than or equal to about 0.5:1, greater than or equal to about 0.7:1, greater than or equal to about 1:1, and less than or equal to about 1.5:1, less than or equal to about 1.2:1, or less than or equal to about 1:1. In the template crystal, a mole ratio of tellurium to selenium may be greater than or equal to about 0.0001:1 and less than or equal to about 0.05:1.

The semiconductor nanoparticle may further include a nanocrystal layer being disposed on the template crystal and including (e.g., a zinc chalcogenide including) zinc and sulfur.

The semiconductor nanoparticle may have a size greater than or equal to about 8 nm, or greater than or equal to about 10 nm, and less than or equal to about 60 nm, less than or equal to about 50 nm, or less than or equal to about 30 nm.

The semiconductor nanoparticle may be configured to emit blue light.

The blue light may have a peak emission wavelength greater than or equal to about 410 nm and less than or equal to about 480 nm.

In a UV-Vis absorption spectrum, the semiconductor nanoparticle may have a first absorption peak wavelength of from 380 nm to 430 nm, 410 nm to 420 nm, 390 nm to 409 nm, or a combination thereof.

In an embodiment, a method for producing the semiconductor nanoparticle includes: obtaining a core including a first zinc chalcogenide; and contacting (e.g., reacting) a zinc precursor and a chalcogen element in the presence of the core within a reaction medium including an organic solvent, wherein the reaction medium further includes a fluorine compound and an alkali metal compound.

The fluorine compound may include an inorganic fluorine compound (e.g., a metal fluoride), hydrofluoric acid, or a combination thereof. The alkali metal compound may include an alkali metal carboxylate. The alkali metal compound may include a cesium carboxylate (e.g., CsCOOR, where R is a C1 to C40 or C2 to C28 hydrocarbon group), a rubidium carboxylate (e.g., RbCOOR, where R is a C1 to C40 or C2 to C28 hydrocarbon group), or a combination thereof.

An amount of the alkali metal in the reaction medium may be greater than or equal to about 0.01 molar percent (mol %) and less than or equal to about 5 mol % based on the zinc precursor.

An embodiment relates to a population of the semiconductor nanoparticle described herein.

In an embodiment, an electroluminescent device includes a first electrode and a second electrode spaced apart from each other, and a light emitting layer disposed between the first electrode and the second electrode, the light emitting layer including the semiconductor nanoparticle described herein.

In an embodiment, an electroluminescent device includes a hole auxiliary layer including a hole transport layer, an electron auxiliary layer including an electron transport layer, and an emission layer disposed between the hole transport layer and the electron transport layer, wherein the emission layer includes the semiconductor nanoparticle described herein.

In an embodiment, a display device or an electronic device may include the electroluminescent device or the semiconductor nanoparticle.

The hole auxiliary layer may include poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene): polystyrene sulfonate (PEDOT:PSS), polyaniline, polypyrrole, a fluorene arylamine compound, N,N,N′,N′-tetrakis(4-methoxyphenyl)-benzidine, 4,4′-bis[N-(1-naphthyl)-N-phenyl-amino]biphenyl (α-NPD), 4,4′,4″-Tris[phenyl(m-tolyl)amino]triphenylamine (m-MTDATA), 4,4′,4″-tris(N-carbazolyl)-triphenylamine (TCTA), 1,1-bis[(di-4-tolylamino)phenyl]cyclohexane (TAPC), NiO, WO₃, MoO₃, a graphene oxide, or a combination thereof.

The hole auxiliary layer may include a hole transporting layer, a hole injection layer, or a combination thereof.

The electron auxiliary layer may include 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinoline)aluminum (Alq₃), tris(8-hydroxyquinoline)gallium (Gaq₃), tris-(8-hydroxyquinoline)indium (Inq₃), bis(8-hydroxyquinoline)zinc (Znq₂), bis(2-(2-hydroxyphenyl)benzothiazolate)zinc (Zn(BTZ)₂), bis(10-hydroxybenzo[h]quinolinato)beryllium (BeBq₂), 8-(4-(4,6-di(naphthalen-2-yl)-1,3,5-triazin-2-yl)phenyl)quinolone (ET204), 8-hydroxyquinolinato lithium (Liq), an n-type doped zinc oxide nanoparticle, a hafnium oxide nanoparticle, or a combination thereof.

The electron auxiliary layer may include an electron transporting layer, an electron injection layer, or a combination thereof.

The display device or the electronic device may include a virtual reality device, an augmented reality device, a portable terminal, a monitor, a laptop, a television, an electronic board, a camera, or an electrical component.

According to an embodiment, a cadmium-free semiconductor nanoparticle is provided, which includes a template crystal having a bipyramidal shape with a predetermined number of a mirror plane. The produced semiconductor nanoparticle may provide an emission film with an increased particle density.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1A illustrates a zinc blende crystal structure of a zinc chalcogenide;

FIG. 1B is a projection of the crystal structure of FIG. 1A in a [111] direction, which represents the stacking sequence of bilayers (BL) of zinc atoms (large circles) and chalcogen element atoms (small circles) in the [111] direction;

FIG. 2A schematically illustrates a cross-section of a template crystal according to an embodiment, and FIG. 2B schematically illustrates a cross-section of a template crystal according to an embodiment. (Py1: first region, Py2: second region, h1: height of the first region, h2: height of the second region, MZ: mirror zone, T: thickness of the mirror zone, L: length of the mirror zone, BL: bilayer);

FIG. 2C schematically illustrates a top view of the template crystal shown in FIG. 2A;

FIG. 2D schematically illustrates a top view of the template crystal shown in FIG. 2B;

FIG. 3 schematically illustrates the reflection of the atomic arrangement occurring at a mirror plane;

FIG. 4A schematically illustrates a cross-section of a template crystal in a semiconductor nanoparticle according to an embodiment, along with its atomic arrangement (Py1: first region, Py2: second region, MZ: mirror zone, BL: bilayer, mp: mirror plane);

FIG. 4B schematically illustrates a cross-section of a template crystal in a semiconductor nanoparticle according to an embodiment, along with its atomic arrangement (Py1: first region, Py2: second region, MZ: mirror zone, BL: bilayer, mp: mirror plane);

FIG. 4C schematically illustrates a cross-section of a template crystal in a semiconductor nanoparticle according to an embodiment, along with its atomic arrangement, in which the mirror zone consists of a single mirror plane (Py1: first region, Py2: second region, MZ: mirror zone);

FIG. 5A is a schematic cross-section of a template crystal in a semiconductor nanoparticle according to an embodiment, the template crystal having an odd number of mirror planes in the mirror zone and having some truncated edges, illustrating facets, edges, and basal planes (mp1, mp2, mp3: mirror planes);

FIG. 5B is a schematic cross-section of a template crystal in a semiconductor nanoparticle according to an embodiment, the template crystal having an even number of mirror planes in the mirror zone and having some truncated edges, illustrating facets, edges, and basal planes (mp1, mp2, mp3, mp4, mp5, mp6: mirror planes);

FIG. 6 schematically illustrates a right angular pyramid (for example, an isosceles right angular pyramid) and a tetrahedron;

FIG. 7 schematically illustrates a cross-sectional view of a QD LED device according to an embodiment;

FIG. 8 schematically illustrates a cross-sectional view of a QD LED device according to an embodiment;

FIG. 9 schematically illustrates a cross-sectional view of a QD LED device according to an embodiment;

FIG. 10 schematically illustrates a cross-sectional view of a QD LED device according to an embodiment;

FIG. 11 schematically illustrates a cross-sectional view of a light-emitting device (RGB pixel) according to an embodiment;

FIG. 12 schematically illustrates a front view of a display panel according to an embodiment;

FIG. 13 schematically illustrates a cross-sectional view of the display panel shown in FIG. 12, taken along IV-IV;

FIG. 14 illustrates an high-resolution scanning transmission electron microscopy (HR-STEM) cross-sectional image (observed along <110> zone axis) of a synthesized template crystal having one mirror plane (i.e., having a single mirror plane);

FIG. 15A illustrates an HR-STEM cross-sectional image (observed along <110> zone axis) of a synthesized template crystal having three mirror planes;

FIG. 15B illustrates the d-spacing measurement results for the template crystal shown in FIG. 15A;

FIG. 16 illustrates an HR-STEM cross-sectional image (observed along <110> zone axis) of a synthesized template crystal having two mirror planes;

FIG. 17A illustrates an HR-STEM cross-sectional image (observed along <110> zone axis) of a synthesized template crystal having six mirror planes.

FIG. 17B illustrates the facet assignment of the template crystal shown in FIG. 17A;

FIG. 18 illustrates tomography images of a template crystal having a triangular bipyramidal shape and a semiconductor nanoparticle including the same during the synthesis process of Example 1;

FIG. 19 illustrates tomography images of a template crystal having a cube-like bipyramidal shape and a semiconductor nanoparticle including the same during the synthesis process of Example 1; and

FIG. 20 illustrates the HR-STEM results of a template crystal synthesized in Comparative Example 1, which does not include a mirror plane.

### DETAILED DESCRIPTION

Hereinafter, with reference to the accompanying drawings, various embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are assigned to the same or similar elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. And in the drawings, for convenience of description, the thickness of some layers and regions are exaggerated.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion, and does not necessarily mean “above” in an opposite direction of gravity.

Relative terms, such as “lower” or “bottom” and “upper” or “top,” may be used herein to describe a relationship of one element to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be understood that, although the terms “first,” “second,” “third,” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

In addition, unless explicitly described to the contrary, the word “comprise” and variations such as “comprises” or “comprising” will be understood to imply the inclusion of stated elements but not the exclusion of any other elements.

In the specification, “cross-section” may mean a cross-section viewed from the side that is cut generally vertically (e.g., substantially vertically to the bottom surface) through the target portion.

Further, the singular includes the plural unless mentioned otherwise.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

In the drawings, the thickness of layers, films, panels, regions, etc., are exaggerated for clarity. Like reference numerals designate like elements throughout the specification.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, values of a work function or (highest occupied molecular orbital (HOMO) or lowest unoccupied molecular orbital (LUMO)) energy levels are expressed as an absolute value from a vacuum level. In addition, a deep, a high, or large work function or energy level means that the absolute value is large when the vacuum level is set to “0 electron volts (eV),” and a shallow, low, or small work function or energy level means that the absolute value is small when the vacuum level is set to “0 eV.”

In an embodiment, the work function may refer to a minimum energy required to remove an electron from a solid metal (e.g., the metal surface) to a vacuum (e.g., the portion just outside the solid surface).

The average may be mean or median. In an embodiment, the average is the mean.

As used herein, the term “peak emission wavelength” is the wavelength at which a given emission spectrum of the light reaches its maximum.

In this specification, “Group” means a group of the periodic table of elements.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” may include Group IIIA and Group IIIB, examples of Group III metals include, but are not limited to, Al, In, Ga, and Tl.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto

As used herein, “Group V” includes Group VA and includes, but is not limited to, nitrogen, phosphorus, arsenic, antimony, and bismuth.

As used herein, “Group VI” includes Group VIA and includes sulfur, selenium, and tellurium, but is not limited thereto.

As used herein, “metal” includes a semi-metal such as Si.

As used herein, when a definition is not otherwise provided, “substituted” refers to replacement of a, e.g., at least one, hydrogen of a compound or the corresponding moiety by a substituent that may be a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C₁ to C₆ alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon group” refers to a group containing carbon and hydrogen (e.g., an aliphatic group such as alkyl, alkenyl, or alkynyl group, or an aromatic group such as aryl group). The hydrocarbon group may be a group having a monovalence or greater valence formed by removal of one or more hydrogen atoms from alkane, alkene, alkyne, or arene. In the hydrocarbon group, a, e.g., at least one, methylene may be replaced by an oxide moiety, a carbonyl moiety, an ester moiety, —NH—, or a combination thereof. Unless otherwise stated to the contrary, the hydrocarbon (alkyl, alkenyl, alkynyl, or aryl) group may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl, hexyl, etc.).

As used herein, when a definition is not otherwise provided, “alkenyl” refers to a linear or branched monovalent hydrocarbon group having one or more carbon-carbon double bond.

As used herein, when a definition is not otherwise provided, “alkynyl” refers to a linear or branched monovalent hydrocarbon group having one or more carbon-carbon triple bond.

As used herein, when a definition is not otherwise provided, “aryl” refers to a group formed by removal of a, e.g., at least one, hydrogen from an aromatic hydrocarbon (e.g., a phenyl or naphthyl group).

As used herein, when a definition is not otherwise provided, “hetero” refers to one including 1 to 3 heteroatoms of N, O, S, Si, P, or a combination thereof.

As used herein, when a definition is not otherwise provided, “alkoxy” means alkyl group linked via an oxygen (i.e., alkyl-O—), such as a methoxy, ethoxy, or sec-butyloxy group.

As used herein, when a definition is not otherwise provided, an “amine group” may be —NRR′, wherein R and R′ are each independently hydrogen, a C1 to C12 alkyl group, a C7 to C20 alkylaryl group, a C7 to C20 arylalkyl group, or a C6 to C18 aryl group.

A description of not containing cadmium (or other toxic heavy metals) may refer to a concentration of cadmium (or a corresponding heavy metal) of less than or equal to about 100 parts per million by weight (ppmw), less than or equal to about 50 ppmw, less than or equal to about 10 ppmw, almost zero, or zero (e.g., undetectable by current methods). In an embodiment, substantially no cadmium, its salt, (or other heavy metal) is present, or, if present, in an amount or impurity level below the detection limit of a given detection means.

As used herein, “substantially” or “approximately” or “about” means not only the stated value, but also the mean within an acceptable range of deviations, considering the errors associated with the corresponding measurement and the measurement of the measured value. For example, “substantially” or “approximately” or “about” can mean within ±10%, 5%, 3%, or 1% or within standard deviation of the stated value.

A nanoparticle refers to a structure having at least one region or characteristic dimension with a nanoscale dimension. In an embodiment, the dimension of the nanoparticle may be less than or equal to about 300 nm, less than or equal to about 250 nm, less than or equal to about 150 nm, less than or equal to about 100 nm, less than or equal to about 50 nm, or less than or equal to about 30 nm. Such a nanoparticle may have any suitable shape. The nanoparticle may have any suitable shape.

For example, semiconductor nanoparticles such as quantum dots may exhibit quantum confinement or exciton confinement. In the present specification, the term “nanoparticles or quantum dots” are not limited in shapes thereof unless specifically defined. Semiconductor nanoparticles, such as quantum dots, may have a size smaller than a diameter of Bohr excitation in the bulk crystal of the same material, and may exhibit a quantum confinement effect. Quantum dots may emit light corresponding to bandgap energies thereof by controlling the size of the nanocrystals as the emission center.

As used herein, a quantum efficiency is a term used interchangeably with quantum yield. Quantum efficiency (or quantum yield) may be measured either in solution or in the solid state (in a composite). In an embodiment, quantum efficiency (or quantum yield) is the ratio of photons emitted to photons absorbed by the nanostructure or population thereof. In an embodiment, quantum efficiency may be measured by any suitable method. For example, for fluorescence quantum yield or efficiency, there may be two methods: an absolute method and a relative method.

In the absolute method, quantum efficiency is obtained by detecting the fluorescence of all samples through an integrating sphere. In the relative method, the quantum efficiency of the unknown sample is calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to photoluminescent (PL) wavelengths thereof, but the present disclosure is not limited thereto.

Unless otherwise stated, numerical ranges stated herein are inclusive. Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value” “at least value” or a “less than or equal to value” or recited with “from” or “to”) may be used to form a numerical range of a given feature. In other words, the upper and lower endpoints set forth for various numerical values may be independently combined to provide a range.

A bandgap energy of the semiconductor nanoparticle may be changed according to a size, a structure, and a composition of nanocrystal. For example, as the size of the quantum dot increases, the quantum dot may have a narrow bandgap energy and an increased emission wavelength. The semiconductor nanocrystal has drawn attention as light emitting materials in various fields of a display device, an energy device, or a bio light emitting device. A semiconductor nanoparticle having electroluminescent properties at a practically applicable level may include harmful heavy metals such as cadmium (Cd), lead, mercury, or a combination thereof. It is desirable to provide a semiconductor nanoparticle that emits light of a desired wavelength (e.g., blue light of relatively low energy) while being substantially free of the harmful heavy metals. In addition, from an environmental point of view, it is desirable to provide a light emitting device or a display device (e.g., emitting blue light) having a light emitting layer based on semiconductor nanoparticles that does not include cadmium, a harmful heavy metal.

In an embodiment, a semiconductor nanoparticle is environmentally friendly as it does not contain cadmium and it can emit blue light of a desired wavelength. In an embodiment, an overall morphological evolution of zinc chalcogenide-based semiconductor nanoparticles (e.g., ZnTeSe/ZnSe/ZnS quantum dots) can be identified using an atomic-resolution microscopy (e.g., a high-resolution scanning transmission electron microscopy) analysis and a three-dimensional tomography. In an embodiment, a template crystal included in the semiconductor nanoparticle can be grown from a ZnTeSe-based core, where a polymorphism including a zinc blende crystal structure may occur, and an unprecedented regularity originating from the number of mirror planes governing the particle shape has been observed. In an embodiment, the template crystal and the semiconductor nanoparticles including the same may include two types of bipyramids. The semiconductor nanoparticle of an embodiment may have a controlled shape and may provide a light-emitting film with a high particle density. The semiconductor nanoparticle can be utilized in various electronic devices, such as photoluminescent-type or electroluminescent-type electronic devices. The electronic device of an embodiment is a self-emissive light-emitting device that is configured to emit desired light upon voltage application, either with or without a separate light source. The semiconductor nanoparticle of an embodiment and the electronic device including the same are desirable from an environmental perspective.

In an embodiment, a semiconductor nanoparticle does not include cadmium and includes a template crystal, which includes a zinc chalcogenide. The zinc chalcogenide may include zinc and selenium. The chalcogen element may be selenium. The zinc chalcogenide or the template crystal may further include tellurium. The template crystal may include a first zinc chalcogenide (or a core including the first zinc chalcogenide), which includes zinc, selenium, and tellurium, and a second zinc chalcogenide (or an intermediate shell including the second zinc chalcogenide), which is disposed on the first zinc chalcogenide and includes zinc and selenium. The first zinc chalcogenide may include ZnTeₓSe₁₋ₓ (where x is greater than 0, greater than or equal to about 0.0001, and less than or equal to about 0.05, less than or equal to about 0.01, less than or equal to about 0.008, or less than or equal to about 0.007). The second zinc chalcogenide may include a zinc selenide.

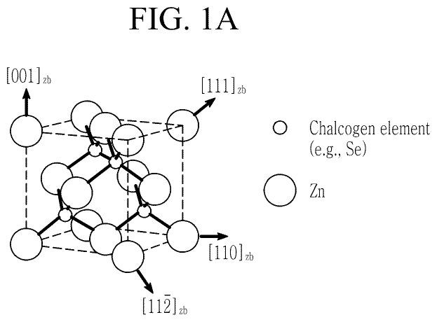

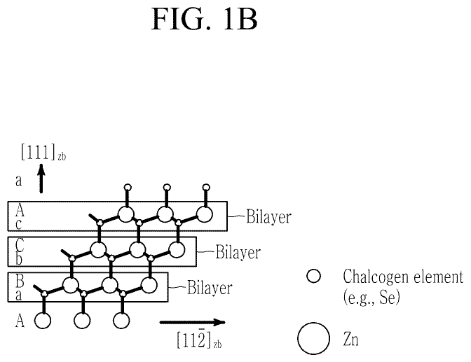

The template crystal may include a zinc blende crystal structure. Referring to FIG. 1A, the zinc blende structure can be described as two interpenetrating systems of a close-packed cubic structure, located at (0,0,0) and (1/4, 1/4, 1/4), respectively. When the zinc blende crystal structure is projected in the <111> direction, the bilayers cationic (i.e., zinc) atoms and anionic (chalcogen element) atoms are stacked in a sequence such as (ABCABC . . . ). In an embodiment of the semiconductor nanoparticle, the template crystal includes such zinc-chalcogen element bilayers (or zinc-chalcogen bilayers).

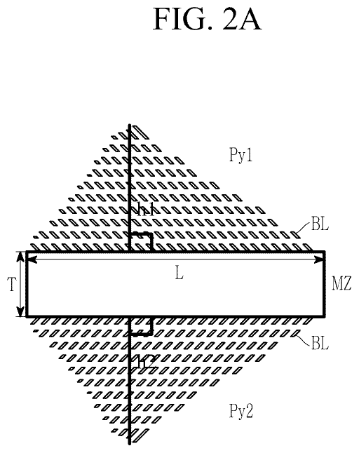

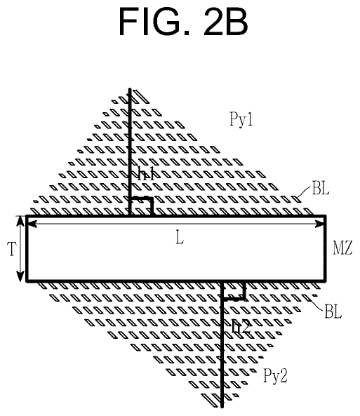

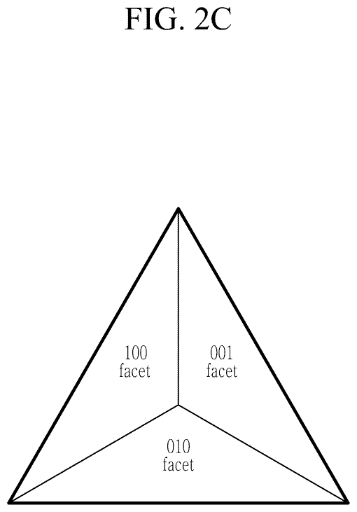

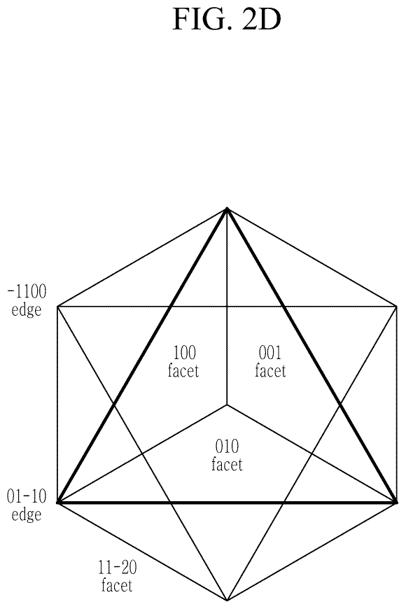

When observed using a scanning transmission electron microscope (e.g., high-resolution scanning transmission electron microscope (HR-STEM), the template crystal includes a first zone (Py1), a second zone (Py2), and a mirror zone (MZ) disposed between the first zone and the second zone (see FIG. 2A, FIG. 2B). The HR-TEM is an imaging mode of a specialized TEM that allows direct imaging of the atomic structure of a given nanostructure. The HR-TEM has a magnification high enough to observe the lattice spacing of inorganic materials, typically in the angstrom range. Generally, such lattice spacing can be identified at an appropriate magnification. Such an HR-TEM equipment may include a series of electron lenses following an electron gun positioned at the top, allowing control of the electron beam. A condenser lens package located above the sample within the column serves to focus the electron beam onto the sample and is sometimes referred to as the illumination system along with the electron gun. A transmission electron microscope system can be operated in two selectable modes: one is a parallel beam mode for forming shadow images, and the other is a convergent beam mode for scanning the sample point by point. The former may be used for high-resolution TEM, while the latter may be used for high-resolution scanning TEM (HR-STEM) to confirm atomic-level arrangements. Such high-resolution TEM or high-resolution STEM devices are commercially available, and by referring to the manuals provided by each manufacturer, images of nanocrystals can be obtained easily and reproducibly.

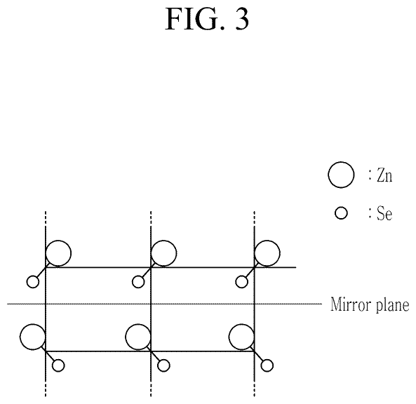

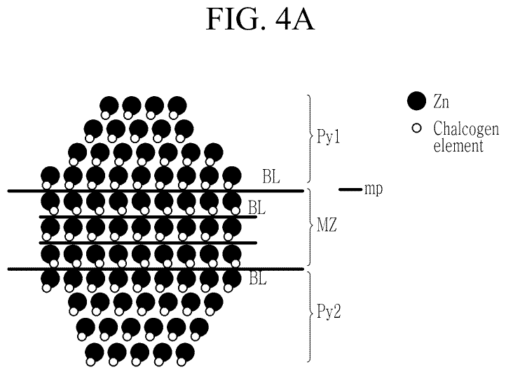

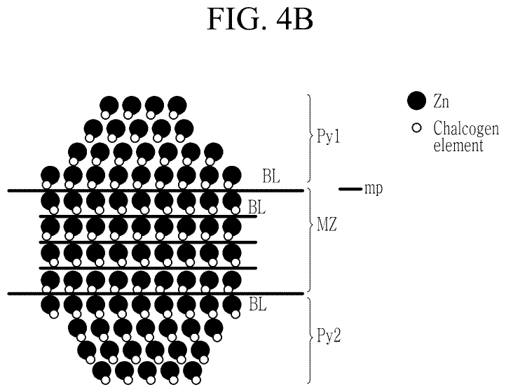

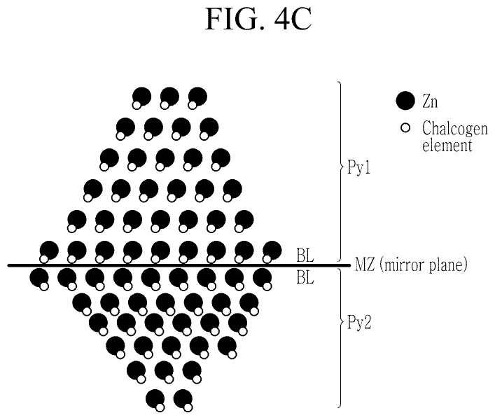

The template crystal includes a mirror zone (for example, as being observed in a projection along the <110> zone axis), and the mirror zone includes at least one (e.g., one, two, three or higher) mirror plane in which (or at which) reflection or reversal of the atomic arrangement direction of zinc-chalcogen element atom bilayers occurs between adjacent zinc-chalcogen element atomic bilayers (BLs). In an embodiment, across the mirror plane, the atomic arrangement directions of adjacent zinc-chalcogen element atomic bilayers may be symmetric to each other (see FIG. 3, FIGS. 4A to 4C). As used herein, the terms “symmetric” or “parallel” include cases that are substantially symmetric or substantially parallel. The atomic arrangement direction of the zinc-chalcogen element may correspond to the lattice fringe in a given electron microscope image.

The mirror zone may include a first surface (e.g., a top mirror plane) facing the first zone and a second surface (e.g., a bottom mirror plane) opposite to the first surface. The first zone may be disposed on (or directly on) the first surface. The second zone may be disposed on (or directly on) the second surface.

In an embodiment, the mirror zone may comprise (e.g., consist of) a single mirror plane. In an embodiment, the mirror zone may include a plurality of mirror planes. The number of mirror planes within the mirror zone may be greater than or equal to about 1, greater than or equal to about 2, greater than or equal to about 3, greater than or equal to about 4, greater than or equal to about 5, greater than or equal to about 6, greater than or equal to about 7, greater than or equal to about 8, or greater than or equal to about 9. The number of mirror planes may be less than or equal to about 15, less than or equal to about 11, or less than or equal to about 10. When the number of mirror planes is one, the mirror zone corresponds to the mirror plane. In an embodiment, the number of mirror planes is plural, and a thickness of the mirror zone may be greater than or equal to about 0.3 nm, greater than or equal to about 1 nm, greater than or equal to about 3 nm, greater than or equal to about 5 nm, greater than or equal to about 7 nm, or greater than or equal to about 9 nm and less than or equal to about 10 nm, or less than or equal to about 7 nm. In the template, the mirror zone may have a thickness of less than or equal to about 50% of a total height of the template crystal. The template crystal may have a total height of less than or equal to about 45 nm, less than or equal to about 30 nm, less than or equal to about 25 nm, less than or equal to about 20 nm, less than or equal to about 15 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, less than or equal to about 2 nm, or less than or equal to about 1 nm. The template crystal may have a total height of greater than or equal to about 5 nm.

In an embodiment, the total height of the template refers to the sum of the height (h1) of the first zone, the thickness (T) of the mirror zone, and the height (h2) of the second zone. The height (h1) of the first zone is defined as the maximum length of the perpendicular dropped from any point on the first zone to the first surface. The height (h2) of the second zone is defined as the maximum length of the perpendicular dropped from any point on the second zone to the second surface (see FIG. 2A and FIG. 2B).

In the mirror zone, a number of zinc-chalcogen element atomic bilayers (BLs) (for example, forming the {111} plane of the zinc chalcogenide) may be greater than or equal to about 1, greater than or equal to about 2, greater than or equal to about 3, greater than or equal to about 4, greater than or equal to about 5, or greater than or equal to about 6. In the mirror zone, the number of zinc-chalcogen element atomic bilayers may be less than or equal to about 20, less than or equal to about 19, less than or equal to about 17, less than or equal to about 15, less than or equal to about 13, less than or equal to about 11, less than or equal to about 9, less than or equal to about 7, or less than or equal to about 3.

In an embodiment, a length (L) of the mirror zone may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, or greater than or equal to about 19 nm. The length (L) of the mirror zone may be less than or equal to about 80 nm, less than or equal to about 70 nm, less than or equal to about 60 nm, less than or equal to about 50 nm, less than or equal to about 45 nm, less than or equal to about 30 nm, or less than or equal to about 20 nm.

The template crystal includes a first region and a second region, which are disposed on an upper surface and a lower surface of the mirror region, respectively. The first region includes a plurality of zinc-chalcogen element bilayers, wherein, in the plurality of zinc-chalcogen element bilayers, zinc atoms and chalcogen element atoms (or bonds thereof) are arranged in a first direction (i.e., exhibiting a first orientation or a first lattice fringe), and in the zinc-chalcogen bilayers of the second region, the zinc atoms and chalcogen element atoms are arranged in a second direction (i.e., exhibiting a second orientation or a second lattice fringe). (See FIG. 4A, FIG. 4B, and FIG. 4C.)

In the template crystal of the semiconductor nanoparticle according to an embodiment, the first direction and the second direction may be symmetric to each other (for example, in a reflection symmetry relationship) (see FIG. 4B and FIG. 4C). In the template crystal of the semiconductor nanoparticle according to an embodiment, the first direction and the second direction may be identical (for example, parallel to each other) (see FIG. 4A). As mentioned above, the terms “symmetric” and “parallel” in the present specification include substantial or approximate symmetry and parallelism. The term “identical direction” includes substantial or approximate identity.

Surprisingly, the present inventors have found that the template crystal produced by the method described herein, or a semiconductor nanoparticle including the same, may exhibit a unique shape as described herein. According to the findings of the present inventors, the number of mirror planes in the mirror region can directly affect the shape of the template crystal. In the template crystal according to an embodiment, the number of mirror planes in the mirror region may be an odd number (for example, 1, 3, 5, or 7 or more), and the first direction and the second direction may be symmetric to each other (for example, in a reflection symmetry relationship) (see FIG. 4B and FIG. 4C). The number of mirror planes in the mirror region may be an even number (for example, 2, 4, 6, or 8 or more), and the first direction and the second direction may be substantially identical (for example, parallel to each other) (see FIG. 4A).

In the template crystal according to an embodiment, the lengths of the zinc-chalcogen bilayers included in the first region may decrease as they extend away from the mirror region (for example, at least in part or entirely), thereby exhibiting an overall shape converging toward the top. In the template crystal according to an embodiment, the lengths of the zinc-chalcogen bilayers included in the second region may decrease as they extend away from the mirror region (for example, at least in part or entirely), thereby exhibiting an overall shape converging toward the top (see FIG. 4A, FIG. 4B, and FIG. 4C). A length of a zinc-chalcogen element bilayer refers to a linear dimension or a length of a straight line extending in a direction substantially perpendicular to the height of each region in a given cross-section (for example, a dimension corresponding to the length (L) of the mirror region).

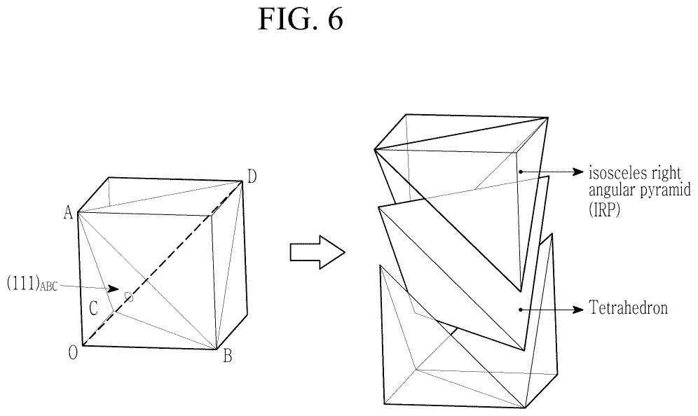

Therefore, the first region and the second region may each independently have a shape of a pyramid. Accordingly, in the first region and the second region, the visible surfaces are triangular in a broad outline, converging toward the top, and provide a shape that is approximately pyramidal for example in a geometric sense. The pyramid may have a polygonal (e.g., triangular, quadrilateral, pentagonal, or hexagonal) base. The pyramid may be a trigonal pyramid (a pyramid with a triangular base). The pyramid may be a right triangular pyramid in which the three visible triangular surfaces are right triangles, or an isosceles right angular pyramid. In an embodiment, the pyramid may be a tetrahedron (see FIG. 6).

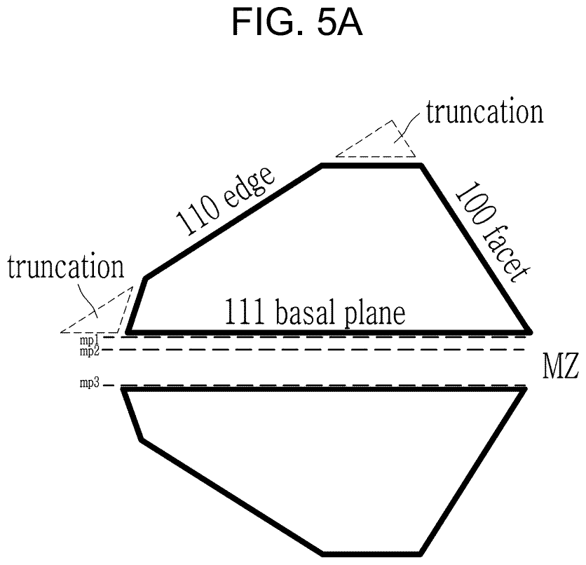

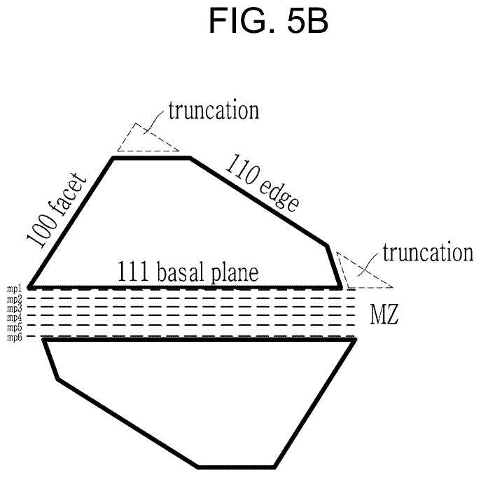

The shape of the pyramid may have one or more (e.g., two, three, or more) edges truncated (see FIGS. 5A and 5B).

FIGS. 5A and 5B illustrate simplified cross-sectional views of template crystals with three and six mirror planes, respectively, depicting the first region, the mirror region, and the second region, in which one or more edges are truncated. FIGS. 5A and 5B together show triangular cross-sections cut by truncation, and the dotted lines labeled with numbers represent mirror planes. Referring to FIGS. 5A and 5B, in the pyramidal shape, the base may be a {111} plane and may be triangular, while the lateral faces, which are triangular, may each be a 100 facet facing a 110 edge.

The mirror region may have a shape of a prism or an antiprism (or a shape similar to an antiprism), and the first surface and the second surface may be the first base and the second base of the prism or the antiprism. In an embodiment, the prism may be a triangular prism. In an embodiment, the antiprism may have the first base and the second base twisted at a predetermined angle with each other. The first base and the second base may be polygons (e.g., triangle, quadrilateral, pentagon, or hexagon). The shape of the mirror region may vary depending on the number of mirror planes included within the mirror region. In an embodiment, an antiprism or a shape similar to the same may refer to a structure in which two bases are twisted at a predetermined angle and the lateral faces include a predetermined number of polygons (e.g., triangle).

In an embodiment, if the number of mirror planes included in the mirror region is an odd number of three or more, the mirror region may take the shape of a prism. In an embodiment, if the number of mirror planes included in the mirror region is an even number of two or more, the mirror region may have a shape of an antiprism or an antiprism-like shape.

In an embodiment, if the number of mirror planes included in the mirror region is an odd number of three or more, the mirror region may take the shape of an antiprism or an antiprism-like shape. In an embodiment, if the number of mirror planes included in the mirror region is an even number of two or more, the mirror region may have a shape of a prism.

In an embodiment, the template crystal may have a shape of a trigonal bipyramid (e.g., an elongated triangular bipyramid). The triangular bipyramid may be a right triangular bipyramid. In an embodiment, the template crystal may have an odd number of mirror planes, and the first region and the second region, both of which have a pyramidal shape, respectively, may be disposed on the first surface and the second surface of the mirror region having a triangular prism shape, thereby forming an elongated bipyramid shape. Referring to FIGS. 2A and 2C, in an embodiment, the template crystal has an odd number of mirror planes in the mirror region, and the atomic arrangement direction in the first region and the atomic arrangement direction in the second region are symmetric. The upper portion of a mirror plane or the first surface (i.e., top mirror plane) of the mirror region and the base of the pyramid in the first region are disposed to substantially overlap with each other, and the lower portion of the mirror plane or the second surface (i.e., bottom mirror plane) of the mirror region and the base of the pyramid in the second region are disposed to substantially overlap with each other. The mirror region may have a triangular prism shape (e.g., where the number of mirror planes is three or more) or a triangular shape (e.g., where the mirror region consists of a single mirror plane). In the embodiment, the resulting template crystal may have a triangular bipyramidal shape as a whole, with its cross-section appearing as shown in FIG. 2A and its top view (e.g., when viewed from above the first region or the second region) appearing as shown in FIG. 2C.

In an embodiment, the template crystal may have a cube-like bipyramidal shape or a gyroelongated bipyramidal shape. In an embodiment, the template crystal may have an even number of mirror planes, and the first region and the second region, which have a pyramidal shape, respectively, may be disposed on the first surface and the second surface of the mirror region (e.g., having an antiprism shape). Referring to FIGS. 2B and 2D, in an embodiment, the template crystal has an even number of mirror planes in the mirror region, and the atomic arrangement direction in the first region and the atomic arrangement direction in the second region are either parallel or identical. The first surface of the mirror region (or the top mirror plane) and the base of the pyramid in the first region are disposed to substantially overlap with each other, while the lower portion of the mirror plane or the second surface of the mirror region (bottom mirror plane) and the base of the pyramid in the second region are disposed to substantially overlap with each other. However, in this case, in the mirror region, the first surface and the second surface may be twisted at a predetermined angle, causing the mirror region to take on a substantially antiprism shape or an antiprism-like shape. In an embodiment, the template crystal may have a cube-like bipyramidal shape as a whole, with its cross-section appearing as shown in FIG. 2B and its top view (e.g., when viewed from above the first region or the second region) appearing as shown in FIG. 2D.

An embodiment of the template crystal may include a first region and a second region, each independently comprising a plurality of zinc-chalcogen element bilayers.

In the first region, the number of zinc-chalcogen bilayers may be greater than or equal to about 3, greater than or equal to about 4, greater than or equal to about 5, greater than or equal to about 6, greater than or equal to about 7, greater than or equal to about 8, greater than or equal to about 9, or greater than or equal to about 10. In the first region, the number of zinc-chalcogen bilayers may be less than or equal to about 20, less than or equal to about 19, less than or equal to about 18, less than or equal to about 17, less than or equal to about 16, less than or equal to about 15, less than or equal to about 14, less than or equal to about 13, less than or equal to about 12, less than or equal to about 11, or less than or equal to about 10. A height of the first region may be greater than or equal to about 0.6 nm, greater than or equal to about 0.9 nm, greater than or equal to about 1 nm, greater than or equal to about 1.2 nm, greater than or equal to about 1.5 nm, greater than or equal to about 1.8 nm, greater than or equal to about 2 nm, greater than or equal to about 2.1 nm, greater than or equal to about 2.4 nm, greater than or equal to about 2.7 nm, greater than or equal to about 3 nm, greater than or equal to about 3.3 nm, greater than or equal to about 3.5 nm, or greater than or equal to about 4 nm. The height of the first region may be less than or equal to about 7 nm, less than or equal to about 6.5 nm, less than or equal to about 6 nm, less than or equal to about 5.5 nm, less than or equal to about 5 nm, less than or equal to about 4.5 nm, less than or equal to about 3.8 nm, or less than or equal to about 3.2 nm.

In the second region, the number of zinc-chalcogen bilayers may be greater than or equal to about 3, greater than or equal to about 4, greater than or equal to about 5, greater than or equal to about 6, greater than or equal to about 7, greater than or equal to about 8, greater than or equal to about 9, or greater than or equal to about 10. In the second region, the number of zinc-chalcogen bilayers may be less than or equal to about 20, less than or equal to about 19, less than or equal to about 18, less than or equal to about 17, less than or equal to about 16, less than or equal to about 15, less than or equal to about 14, less than or equal to about 13, less than or equal to about 12, less than or equal to about 11, or less than or equal to about 10. A height of the second region may be greater than or equal to about 0.6 nm, greater than or equal to about 0.9 nm, greater than or equal to about 1 nm, greater than or equal to about 1.2 nm, greater than or equal to about 1.5 nm, greater than or equal to about 1.8 nm, greater than or equal to about 2 nm, greater than or equal to about 2.1 nm, greater than or equal to about 2.4 nm, greater than or equal to about 2.7 nm, greater than or equal to about 3 nm, greater than or equal to about 3.3 nm, greater than or equal to about 3.5 nm, or greater than or equal to about 4 nm. The height of the second region may be less than or equal to about 7 nm, less than or equal to about 6.5 nm, less than or equal to about 6 nm, less than or equal to about 5.5 nm, less than or equal to about 5 nm, less than or equal to about 4.5 nm, less than or equal to about 3.8 nm, or less than or equal to about 3.2 nm.

In an embodiment, in a two-dimensional image obtained by an electron microscope, the shape of the first region and the shape of the second region may be in a substantially reflective symmetrical relationship along a mirror plane. In an embodiment, the horizontally flipped shape of the first region and the shape of the second region may be in a substantially reflective symmetrical relationship along a mirror plane.

The semiconductor nanoparticle may further include a nanocrystal layer comprising zinc and sulfur (e.g., including zinc sulfide) and being disposed on the template crystal. In an embodiment, the semiconductor nanoparticle may have a shape as described herein, similar to the template crystal (e.g., a trigonal bipyramidal or cube-like bipyramidal shape), which may be advantageous for the self-assembled particle arrangement during the formation of the nanocrystal layer. In an embodiment, the template crystal or the semiconductor nanoparticle may have an odd number of mirror planes (e.g., one mirror plane or three or more mirror planes) or a mirror region including the same, and may exhibit a triangular bipyramidal shape (e.g., a right triangular bipyramidal shape). In an embodiment, the template crystal or the semiconductor nanoparticle may have an even number of mirror planes (e.g., two or more mirror planes) or a mirror region including the same, and may have a cube-like bipyramidal shape. The semiconductor nanoparticle including the nanocrystal layer may have a structure in which at least one (or at least two, at least three, or at least four) edges or vertices in the bipyramidal shape are developed, and may include at least one (or at least two, at least three, or at least four) pods.

The semiconductor nanoparticle may have a size of greater than or equal to about 8 nm, greater than or equal to about 10 nm, greater than or equal to about 11 nm, or greater than or equal to about 12 nm. The semiconductor nanoparticle may have a size of less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, less than or equal to about 12 nm, less than or equal to about 11 nm, or less than or equal to about 11 nm. Through controlled crystal growth, the semiconductor nanoparticle in an embodiment may exhibit a more uniform particle shape. In an embodiment, the semiconductor nanoparticle may exhibit improved shape parameters (e.g., solidity, circularity, etc.). The (average) size of the semiconductor nanoparticle may be greater than or equal to about 5 nm, for example, greater than or equal to about 10 nm, where the size of the semiconductor nanoparticle refers to an equivalent diameter calculated assuming a spherical shape from a two-dimensional electron microscope image of the semiconductor nanoparticle. The size of the semiconductor nanoparticle may be an average value (e.g., mean average).

The semiconductor nanoparticle in an embodiment may have an average circularity value of less than or equal to about 0.84, less than or equal to about 0.8, less than or equal to about 0.75, less than or equal to about 0.71, less than or equal to about 0.7, less than or equal to about 0.69, less than or equal to about 0.68, less than or equal to about 0.67, less than or equal to about 0.66, less than or equal to about 0.65, less than or equal to about 0.63, less than or equal to about 0.62, or less than or equal to about 0.61. The semiconductor nanoparticle in an embodiment may have an average circularity value greater than or equal to about 0.5, greater than or equal to about 0.52, or greater than or equal to about 0.53.

As used herein, “circularity” refers to a value obtained using a two-dimensional image obtained by TEM analysis and is defined with reference to the definition provided in the ImageJ User Guide (v1.46r), and is determined by the following equation:

4π×{[Area]/[Perimeter]²}

Circularity ranges from 0 (infinitely elongated polygon) to 1 (perfect circle).

The standard deviation of the circularity may be less than or equal to about 10%, less than or equal to about 9%, less than or equal to about 8%, less than or equal to about 7%, or less than or equal to about 6.7% of the average circularity. The standard deviation of the circularity may be greater than or equal to about 1%, greater than or equal to about 3%, greater than or equal to about 5%, or greater than or equal to about 5.5% of the average circularity.

The semiconductor nanoparticle in an embodiment may have an average solidity value greater than or equal to about 0.9, for example, greater than or equal to about 0.91, greater than or equal to about 0.92, greater than or equal to about 0.93, greater than or equal to about 0.94, or greater than or equal to about 0.95.

As used herein, “solidity” refers to the ratio (B/A) of the area B of a two-dimensional image of a quantum dot to the area A of its convex hull, as determined by electron microscope analysis. The “convex hull” is defined as the smallest convex set of points that includes all points constituting the given two-dimensional image of the quantum dot obtained by electron microscope analysis (see FIG. 1). The solidity value may be obtained using an image (e.g., a two-dimensional image) acquired from an electron microscope (e.g., a transmission electron microscope) and commercially available image analysis software such as Image J.

In the template or the semiconductor nanoparticle, a mole ratio of selenium to zinc (Se:Zn) may be greater than or equal to about 0.5:1, greater than or equal to about 0.55:1, greater than or equal to about 0.6:1, greater than or equal to about 0.65:1, greater than or equal to about 0.7:1, greater than or equal to about 0.75:1, greater than or equal to about 0.8:1, greater than or equal to about 0.85:1, greater than or equal to about 0.9:1, greater than or equal to about 0.95:1, or greater than or equal to about 1:1. In the template crystal or the semiconductor nanoparticle, the mole ratio of selenium to zinc may be less than or equal to about 1.5:1, less than or equal to about 1.4:1, less than or equal to about 1.3:1, less than or equal to about 1.2:1, less than or equal to about 1.1:1, less than or equal to about 1:1, less than or equal to about 0.97:1, less than or equal to about 0.95:1, less than or equal to about 0.93:1, less than or equal to about 0.91:1, or less than or equal to about 0.89:1.

In the template crystal or the semiconductor nanoparticle, a mole ratio of tellurium to selenium (Te:Se) may be greater than or equal to about 0.0001:1 and less than or equal to about 0.05:1. In the template crystal or the semiconductor nanoparticle, the mole ratio of tellurium to selenium may be greater than or equal to about 0.0001:1, greater than or equal to about 0.00015:1, greater than or equal to about 0.0002:1, greater than or equal to about 0.00025:1, greater than or equal to about 0.0003:1, greater than or equal to about 0.00035:1, greater than or equal to about 0.0004:1, greater than or equal to about 0.00045:1, greater than or equal to about 0.0005:1, greater than or equal to about 0.00055:1, greater than or equal to about 0.0006:1, greater than or equal to about 0.00065:1, greater than or equal to about 0.0007:1, greater than or equal to about 0.00075:1, greater than or equal to about 0.0008:1, greater than or equal to about 0.00085:1, greater than or equal to about 0.0009:1, greater than or equal to about 0.00095:1, greater than or equal to about 0.001:1, greater than or equal to about 0.0015:1, greater than or equal to about 0.002:1, greater than or equal to about 0.0025:1, greater than or equal to about 0.003:1, greater than or equal to about 0.0035:1, greater than or equal to about 0.004:1, or greater than or equal to about 0.0045:1. In the template crystal or the semiconductor nanoparticle, the mole ratio of tellurium to selenium may be less than or equal to about 0.1:1, less than or equal to about 0.08:1, less than or equal to about 0.07:1, less than or equal to about 0.06:1, less than or equal to about 0.05:1, less than or equal to about 0.045:1, less than or equal to about 0.04:1, less than or equal to about 0.035:1, less than or equal to about 0.03:1, less than or equal to about 0.025:1, less than or equal to about 0.02:1, less than or equal to about 0.015:1, less than or equal to about 0.01:1, less than or equal to about 0.009:1, less than or equal to about 0.008:1, less than or equal to about 0.007:1, less than or equal to about 0.006:1, or less than or equal to about 0.005:1.

In the template crystal or the semiconductor nanoparticle, a mole ratio of tellurium to zinc (Te:Zn) may be less than or equal to about 0.02:1, less than or equal to about 0.019:1, less than or equal to about 0.018:1, less than or equal to about 0.017:1, less than or equal to about 0.016:1, less than or equal to about 0.015:1, less than or equal to about 0.014:1, less than or equal to about 0.013:1, less than or equal to about 0.012:1, less than or equal to about 0.011:1, less than or equal to about 0.01:1, less than or equal to about 0.009:1, less than or equal to about 0.008:1, less than or equal to about 0.007:1, less than or equal to about 0.006:1, or less than or equal to about 0.005:1. The mole ratio of tellurium to zinc may be greater than or equal to about 0.0001:1, greater than or equal to about 0.0002:1, greater than or equal to about 0.0003:1, greater than or equal to about 0.0004:1, greater than or equal to about 0.0005:1, greater than or equal to about 0.0006:1, greater than or equal to about 0.0007:1, greater than or equal to about 0.0008:1, greater than or equal to about 0.0009:1, greater than or equal to about 0.001:1, greater than or equal to about 0.0011:1, greater than or equal to about 0.0012:1, greater than or equal to about 0.0013:1, greater than or equal to about 0.0014:1, or greater than or equal to about 0.0015:1.

In the semiconductor nanoparticle, the mole ratio of sulfur to zinc (S:Zn) may be greater than or equal to about 0.1:1, for example, greater than or equal to about 0.15:1, greater than or equal to about 0.2:1, greater than or equal to about 0.25:1, or greater than or equal to about 0.3:1. In the semiconductor nanoparticle, the mole ratio of sulfur to zinc may be less than or equal to about 1.5:1, less than or equal to about 1.3:1, less than or equal to about 1.2:1, less than or equal to about 1:1, less than or equal to about 0.9:1, less than or equal to about 0.8:1, less than or equal to about 0.7:1, less than or equal to about 0.6:1, less than or equal to about 0.5:1, or less than or equal to about 0.45:1.

The semiconductor nanoparticle may be configured to emit blue light. An e peak emission wavelength of the semiconductor nanoparticle or the blue light may be greater than or equal to about 410 nm, greater than or equal to about 420 nm, greater than or equal to about 430 nm, for example, greater than or equal to about 440 nm, greater than or equal to about 445 nm, greater than or equal to about 450 nm, or greater than or equal to about 455 nm, and may be less than or equal to about 480 nm, less than or equal to about 475 nm, less than or equal to about 470 nm, less than or equal to about 465 nm, less than or equal to about 460 nm, or less than or equal to about 455 nm. The blue light may have the peak emission wavelength in the range of about 450 nm to about 470 nm (e.g., about 465 nm or about 460 nm). In the ultraviolet-visible (UV-Vis) absorption spectrum, the first absorption peak wavelength of the semiconductor nanoparticle may be in the range of about 410 nm to about 420 nm, about 390 nm to about 409 nm, or a combination thereof.

The semiconductor nanoparticle in an embodiment may exhibit an enhanced quantum efficiency of greater than or equal to about 30%, greater than or equal to about 50%, greater than or equal to about 70%, greater than or equal to about 71%, greater than or equal to about 72%, greater than or equal to about 73%, greater than or equal to about 74%, or greater than or equal to about 75%. The quantum dot may exhibit a quantum efficiency of greater than or equal to about 80%, greater than or equal to about 85%, or greater than or equal to about 90%. The semiconductor nanoparticle may have a full width at half maximum (FWHM) of the emission peak of less than or equal to about 50 nm, less than or equal to about 45 nm, less than or equal to about 40 nm, less than or equal to about 35 nm, less than or equal to about 30 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, or less than or equal to about 13 nm.

In an embodiment of the semiconductor nanoparticle, the template crystal may have an elongated bipyramidal shape, and the mole ratio of Se:Zn or the mole ratio of S:Zn may each be in the range described herein for example of about 1:1 to about 1.5:1. The first absorption peak wavelength in the UV-Vis absorption spectrum of the semiconductor nanoparticle or the template crystal may be in the range of about 410 nm to about 420 nm, and the peak emission wavelength may be in the range of about 430 nm to about 470 nm. In an embodiment of the semiconductor nanoparticle, the template crystal may have a gyroelongated bipyramidal shape, and the mole ratio of Se/Zn or the mole ratio of S/Zn may be in the range described herein, for example, of about 0.5:1 to about 0.9:1. The first absorption peak wavelength in the UV-Vis absorption spectrum of the semiconductor nanoparticle or the template crystal may be in the range of about 390 nm to about 409 nm, and the peak emission wavelength may be in the range of about 420 nm to about 460 nm.

An embodiment relates to a method for producing the semiconductor nanoparticle. The method includes obtaining a nanocrystal comprising a first zinc chalcogenide (hereinafter also referred to as a “core”) and reacting a zinc precursor and a chalcogen element in a reaction medium comprising an organic solvent in the presence of the core to obtain a template crystal. The reaction medium further includes a fluorine compound and an alkali metal compound. In an embodiment, the reaction medium may further include a chloride, such as a metal chloride, for example, zinc chloride. The method may further include forming a nanocrystal layer comprising zinc sulfide by reacting a zinc precursor with a sulfur precursor in the presence of the template crystal.

The method for obtaining a nanocrystal comprising a first zinc chalcogenide is not particularly limited and may be appropriately selected in consideration of the desired emission wavelength. In an embodiment, the core may be obtained by preparing a zinc precursor solution comprising a zinc precursor and an organic ligand, preparing a selenium precursor and a tellurium precursor, heating the zinc precursor solution to a core formation reaction temperature, adding the selenium precursor and the tellurium precursor optionally together with an organic ligand, and conducting a reaction.

The fluorine compound may include an inorganic fluorine compound (e.g., a metal fluoride), hydrofluoric acid, or a combination thereof. The alkali metal compound may include sodium, lithium, potassium, cesium, rubidium, or a combination thereof. The alkali metal compound may include a sodium carboxylate, a lithium carboxylate, a potassium carboxylate, a cesium carboxylate, a rubidium carboxylate, or a combination thereof. The carboxylate may include a moiety represented by RCOO, where R is an aliphatic or aromatic hydrocarbon group (e.g., an alkyl group, an alkenyl group, an alkynyl group, an aryl group, etc.) of C1-C40, C2-C30, C5-C24, C4-C22, C8-C18, or a combination thereof.

The alkali metal compound may include an alkali metal acetate, an alkali metal oleate, an alkali metal laurate, an alkali metal myristate, an alkali metal stearate, or a combination thereof. The alkali metal compound may include a cesium acetate, a cesium oleate, a cesium laurate, a cesium myristate, a cesium stearate, a rubidium acetate, a rubidium oleate, a rubidium laurate, a rubidium myristate, a rubidium stearate, or a combination thereof.

An amount of the fluorine compound in the reaction medium may be appropriately selected. An amount of the fluorine compound as used may be greater than or equal to about 0.05 millimole (mmol), greater than or equal to about 0.1 mmol, greater than or equal to about 0.15 mmol, greater than or equal to about 0.2 mmol, greater than or equal to about 0.25 mmol, greater than or equal to about 0.3 mmol, greater than or equal to about 0.35 mmol, greater than or equal to about 0.4 mmol, greater than or equal to about 0.45 mmol, greater than or equal to about 0.5 mmol, greater than or equal to about 0.55 mmol, greater than or equal to about 0.6 mmol, greater than or equal to about 0.7 mmol, greater than or equal to about 0.75 mmol, greater than or equal to about 0.8 mmol, greater than or equal to about 0.85 mmol, greater than or equal to about 0.9 mmol, or greater than or equal to about 1 mmol per 10 mL of a core solution having a predetermined optical density (e.g., 0.54) at a first absorption wavelength of a UV-Vis absorption spectrum. The amount of the fluorine compound as used may be less than or equal to about 3 mmol, less than or equal to about 2.5 mmol, less than or equal to about 2 mmol, or less than or equal to about 1.5 mmol per 10 milliliters (mL) of the core solution having a predetermined optical density.

In an embodiment, a metal chloride may be used, and an amount of the metal chloride (e.g., zinc chloride) as used may be greater than or equal to about 0.01 mmol, for example, greater than or equal to about 0.02 mmol, greater than or equal to about 0.03 mmol, greater than or equal to about 0.04 mmol, greater than or equal to about 0.05 mmol, greater than or equal to about 0.06 mmol, greater than or equal to about 0.07 mmol, greater than or equal to about 0.08 mmol, greater than or equal to about 0.09 mmol, greater than or equal to about 0.1 mmol, greater than or equal to about 0.11 mmol, greater than or equal to about 0.12 mmol, greater than or equal to about 0.13 mmol, greater than or equal to about 0.14 mmol, or greater than or equal to about 0.15 mmol per 10 mL of a quantum dot (core) solution having an optical density of 0.54 at the first absorption peak wavelength. The amount of the metal chloride (e.g., zinc chloride) as used may be less than or equal to about 3 mmol, for example, less than or equal to about 2.5 mmol, less than or equal to about 2 mmol, or less than or equal to about 1.5 mmol per 10 mL of the quantum dot solution having an optical density of 0.54 at the first absorption peak wavelength.

An amount of the alkali metal compound in the reaction medium may be greater than or equal to about 0.005 mol %, greater than or equal to about 0.007 mol %, greater than or equal to about 0.01 mol %, greater than or equal to about 0.03 mol %, greater than or equal to about 0.05 mol %, greater than or equal to about 0.07 mol %, greater than or equal to about 0.09 mol %, greater than or equal to about 0.1 mol %, greater than or equal to about 0.105 mol %, greater than or equal to about 0.15 mol %, greater than or equal to about 0.3 mol %, greater than or equal to about 0.5 mol %, greater than or equal to about 0.7 mol %, greater than or equal to about 0.9 mol %, greater than or equal to about 1 mol %, greater than or equal to about 1.05 mol %, greater than or equal to about 2 mol %, greater than or equal to about 2.1 mol %, greater than or equal to about 2.3 mol %, greater than or equal to about 2.4 mol %, greater than or equal to about 2.5 mol %, greater than or equal to about 2.6 mol %, greater than or equal to about 2.7 mol %, greater than or equal to about 2.8 mol %, or greater than or equal to about 2.9 mol % relative to the zinc precursor. The amount of the alkali metal compound in the reaction medium may be less than or equal to about 15 mol %, less than or equal to about 10 mol %, less than or equal to about 7 mol %, less than or equal to about 5 mol %, less than or equal to about 3 mol %, less than or equal to about 1.5 mol %, or less than or equal to about 0.9 mol % relative to the zinc precursor.

By including the alkali metal compound together with the fluorine compound in the reaction medium, the shape of the template crystals can be controlled.

In an embodiment, the amount of the alkali metal compound may be from about 0.005 mol % to about 0.7 mol %, from about 0.01 mol % to about 0.5 mol %, or from about 0.05 mol % to about 0.3 mol % relative to the zinc precursor, and among the produced template crystals, for example, those having an odd number of mirror planes and a triangular bipyramidal shape may be predominant.

In an embodiment, the amount of the alkali metal compound may be from about 0.71 mol % to about 7 mol %, from about 0.9 mol % to about 5 mol %, or from about 0.95 mol % to about 3 mol % relative to the zinc precursor, and among the produced template crystals, for example, those having an even number of mirror planes and a cubic-like bipyramidal shape may be predominant.

Without wishing to be bound by any theory, it is believed that the reaction rate of template crystal formation may significantly increase due to the coexistence of the fluorine compound and the alkali metal compound. Accordingly, the shape of the template crystals may be controlled to exhibit the characteristics described herein (e.g., composition and/or shape).

The zinc precursor or zinc compound may include a Zn metal powder, ZnO, an alkylated Zn compound (e.g., a (C2 to C30 dialkyl)zinc such as diethylzinc), Zn alkoxide (e.g., zinc ethoxide), Zn carboxylate (e.g., zinc acetate), Zn nitrate, Zn perchlorate, Zn sulfate, Zn acetylacetonate, Zn halide (e.g., zinc chloride), Zn cyanide, Zn hydroxide, zinc carbonate, zinc peroxide, or a combination thereof. Examples of zinc precursors may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, or a combination thereof.

The selenium precursor (or the first selenium precursor, the second selenium precursor, or a combination thereof) may include, but is not limited to, selenium-trioctylphosphine (Se-TOP), selenium-tributylphosphine (Se-TBP), selenium-triphenylphosphine (Se-TPP), selenium-diphenylphosphine (Se-DPP), or a combination thereof.

The tellurium precursor may include, but is not limited to, tellurium-tributylphosphine (Te-TBP), tellurium-triphenylphosphine (Te-TPP), tellurium-diphenylphosphine (Te-DPP), or a combination thereof.

The sulfur precursor may include hexanethiol, octanethiol, decanethiol, dodecanethiol, hexadecanethiol, mercapto propyl silane, sulfur-trioctylphosphine (S-TOP), sulfur-tributylphosphine (S-TBP), sulfur-triphenylphosphine (S-TPP), sulfur-trioctylamine (S-TOA), bis(trialkylsilyl)sulfide, bis(trialkylsilylalkyl)sulfide (e.g., bis(trimethylsilylmethyl) sulfide), ammonium sulfide, sodium sulfide, or a combination thereof.

The organic solvent (the first organic solvent, the second organic solvent, or a combination thereof) may include a C6 to C22 primary amine such as oleyl amine or hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctylphosphine) substituted with a, e.g., at least one (e.g., 1, 2, or 3), C6 to C22 alkyl groups, a primary, secondary, or tertiary phosphine oxide (e.g., trioctylphosphine oxide) substituted with a (e.g., 1, 2, or 3) C6 to C22 alkyl groups, a C12 to C22 aromatic ether such as phenyl ether or benzyl ether, or a combination thereof.

The semiconductor nanoparticle may include, for example, an organic ligand (a second organic ligand) on the surface. The organic ligand coordinates the surface of the produced nanocrystals, and not only enables the nanocrystals to be well dispersed in the solution phase, but can also affect the luminescent and electrical properties. The organic ligand (e.g., a first organic ligand and/or a second organic ligand) may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂PO(OH), or a combination thereof (wherein R and R′ each independently include, e.g., may be, a substituted or unsubstituted C1 to C40 (or C3 to C24) aliphatic hydrocarbon group, or a substituted or unsubstituted C6 to C40 (or C6 to C24) aromatic hydrocarbon group, or a combination thereof). The ligand may be used alone or as a mixture of two or more compounds.

Specific examples of the organic ligand compound may include methane thiol, ethane thiol, propane thiol, butane thiol, pentane thiol, hexane thiol, octane thiol, dodecane thiol, hexadecane thiol, octadecane thiol, benzyl thiol; methyl amine, ethyl amine, propyl amine, butyl amine, pentyl amine, hexyl amine, octyl amine, dodecyl amine, hexadecyl amine, oleyl amine, octadecyl amine, dimethyl amine, diethyl amine, dipropyl amine; methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, palmitic acid, stearic acid; phosphine such as methyl phosphine, ethyl phosphine, propyl phosphine, butyl phosphine, pentyl phosphine, tributylphosphine, or trioctylphosphine; a phosphine oxide compound such as methyl phosphine oxide, ethyl phosphine oxide, propyl phosphine oxide, butyl phosphine oxide, or trioctylphosphine oxide; a diphenyl phosphine or triphenyl phosphine compound, or an oxide compound thereof; phosphonic acid, and the like, but are not limited thereto. The organic ligand compound may be used alone or in a mixture of two or more compounds. In an embodiment, the organic ligand compound may be a combination of RCOOH and amine (e.g., RNH₂, R₂NH, R₃N, or a combination thereof).

A temperature of the core formation reaction may be greater than or equal to about 280° C., for example, greater than or equal to about 290° C. The reaction time for core formation is not particularly limited and may be appropriately selected. For example, the reaction time may be greater than or equal to about 5 minutes, greater than or equal to about 10 minutes, greater than or equal to about 15 minutes, greater than or equal to about 20 minutes, greater than or equal to about 25 minutes, greater than or equal to about 30 minutes, greater than or equal to about 35 minutes, greater than or equal to about 40 minutes, greater than or equal to about 45 minutes, or greater than or equal to about 50 minutes, but is not limited thereto. For example, the reaction time may be less than or equal to about 2 hours, but is not limited thereto. The size of the core may be adjusted by controlling the reaction time.

Reaction conditions, such as the reaction temperature and time, for the template crystal formation may be appropriately selected in consideration of the desired composition of the template and the types of compounds used. The reaction time for forming the template crystal may be greater than or equal to about 5 minutes, greater than or equal to about 10 minutes, greater than or equal to about 15 minutes, or greater than or equal to about 20 minutes, and may be less than or equal to about 5 hours, less than or equal to about 4 hours, less than or equal to about 3 hours, less than or equal to about 2 hours, or less than or equal to about 1 hour, but is not limited thereto. In an embodiment, a first medium including an organic solvent and, optionally, an organic ligand may be heated (or subjected to vacuum treatment) under vacuum to a predetermined temperature (e.g., greater than or equal to about 100° C.), and then reheated (pretreated) to a predetermined temperature (e.g., greater than or equal to about 100° C.) under an inert gas atmosphere. The first medium may further include a zinc precursor or a zinc compound for the precursor and/or an alkali metal compound. A core may be introduced into the pretreated first medium, and a zinc precursor, a selenium precursor, and, optionally, a sulfur precursor may be sequentially or simultaneously introduced, followed by heating to a predetermined reaction temperature to synthesize the template crystal.

In an embodiment, a subsequent reaction (e.g., formation of a zinc sulfide-based nanocrystal layer) may be carried out in the presence of the synthesized template crystal. In an embodiment, the synthesized template crystal may be separated from the reaction medium and, optionally, washed before being added to a medium for a subsequent reaction. In an embodiment, a precursor for the subsequent reaction (e.g., a sulfur precursor and, optionally, an additional zinc precursor) may be added to the reaction medium containing the synthesized template crystal to synthesize a semiconductor nanoparticle.

The zinc precursor and the chalcogen element precursors may be sequentially introduced as a mixture with different ratios over the reaction time to form a shell with a desired composition (e.g., a gradient or multilayered structure). In an embodiment, a first layer may be formed by reacting a zinc precursor with a selenium precursor, followed by the formation of a second layer by reacting a zinc precursor with a sulfur precursor. The reaction temperature may be greater than or equal to about 320° C., greater than or equal to about 330° C., or greater than or equal to about 340° C. The reaction temperature may be less than or equal to about 380° C., less than or equal to about 370° C., less than or equal to about 360° C., or less than or equal to about 350° C.

In the method of an embodiment, the reaction medium may further include a zinc precursor, the alkali metal compound, and an organic ligand, and additional zinc precursor and selenium precursor may be added to the reaction medium along with the prepared core. The amount and concentration of each precursor in the reaction system may be selected in consideration of the desired composition of the core and template crystal, as well as the reactivity between the precursors.

After the completion of the reaction, when a nonsolvent is added to the reaction product (the reaction product containing the template crystal or semiconductor nanoparticles), the ligand-coordinated nanocrystals may be separated. The nonsolvent may be a polar solvent that is miscible with the solvent used in the core formation reaction, shell formation reaction, or a combination thereof and is not capable of dissolving the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof. The semiconductor nanocrystal particle may be separated through centrifugation, sedimentation, chromatography, or distillation. The separated nanocrystal particle may be added to a washing solvent and washed, if needed. The washing solvent has no particular limit and may not dissolve the nanocrystal particle and may have a similar solubility parameter to that of the ligand and may, for example, include hexane, heptane, octane, chloroform, toluene, benzene, or the like, or a combination thereof.

In an embodiment, an electronic device includes the semiconductor nanocrystal described herein. The device may include (or may be), but is not limited to, a display device, a light-emitting diode (LED), an organic light-emitting diode (OLED), a quantum dot LED, a sensor, a solar cell, an imaging sensor, or a liquid crystal display (LCD). In an embodiment, the electronic device may be a photoluminescent device (e.g., a quantum dot sheet, a quantum dot rail, a lighting device, or a liquid crystal display device) or an electroluminescent device (e.g., a QD LED).

In an embodiment, the electronic device may include a quantum dot sheet, and the aforementioned semiconductor nanocrystals may be incorporated within the quantum dot sheet (e.g., in the form of a semiconductor nanocrystal-polymer composite).

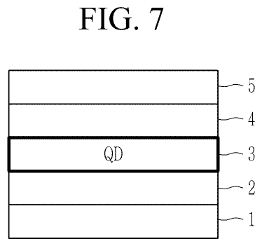

An embodiment of the electroluminescent device includes a first electrode 1 and a second electrode 5 that are spaced apart (e.g., facing each other); and an emission layer (or a light emitting layer) 3, which is disposed between the first electrode and the second electrode, includes the semiconductor nanoparticles, and does not include cadmium (see FIG. 7). The first electrode may include an anode, and the second electrode may include a cathode. Alternatively, the first electrode may include a cathode, and the second electrode may include an anode. The electroluminescent device may further include a hole auxiliary layer 2, including a hole transport layer, between the emission layer 3 and the first electrode 1. The electroluminescent device may further include an electron auxiliary layer 4, including an electron transport layer, between the emission layer 3 and the second electrode 5.

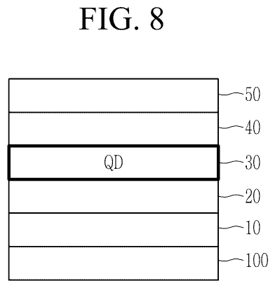

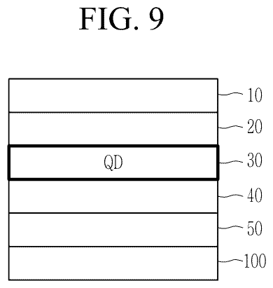

In the electroluminescent device as described in FIG. 8, the first electrode 10 or the second electrode 20 may be disposed on a (transparent) substrate 100. As described in FIG. 9, the transparent substrate may be a light extraction surface.

Referring to FIGS. 8 and 9, an emission layer (or a light emitting layer) 30 may be disposed between a first electrode (e.g., an anode) 10 and a second electrode (e.g., a cathode) 50. The second electrode (or the cathode) 50 may include an electron-injecting conductor. The first electrode (or the anode) 10 may include a hole-injecting conductor. The work function of the electron/hole-injecting conductor included in the second electrode and the first electrode can be appropriately adjusted and is not particularly limited. For example, the second electrode may have a small work function, and the first electrode may have a relatively large work function, or vice versa.

The electron/hole injection conductors may include a metal-based material (e.g., a metal, a metal compound, an alloy, or a combination thereof) (e.g., aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The electrode(s) may be patterned. The first electrode, the second electrode, or a combination thereof may be disposed on a (e.g., insulating) substrate. The substrate may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light-transmitting electrode may be disposed on a (e.g., insulating) transparent substrate. The substrate may be a rigid or a flexible substrate. The substrate may include a plastic or organic material such as a polymer, an inorganic material such as a glass, or a metal.

The light-transmitting electrode may have a light transmittance of greater than or equal to about 50%, greater than or equal to about 60%, greater than or equal to about 70%, greater than or equal to about 80%, or greater than or equal to about 90%, for example, from about 80% to about 100%, from about 85% to about 95%, or a combination thereof.

The light-transmitting electrode may be made of, for example, a transparent conductor such as indium tin oxide (ITO) or indium zinc oxide (“IZO”), gallium indium tin oxide, zinc indium tin oxide, titanium nitride, polyaniline, LiF/Mg:Ag, or the like, or a metal thin film of a single layer or a plurality of layers, but is not limited thereto. If one of the first electrode and the second electrode is an opaque electrode, the opaque electrode may be made of an opaque conductor such as aluminum (Al), a lithium-aluminum (Li:Al) alloy, a magnesium-silver (Mg:Ag) alloy, or a lithium fluoride-aluminum (LiF:Al) compound. In the case of the alloy electrode, the ratio between each material may be appropriately adjusted, for example, in the range of from about 1:0.1 to about 1:10, from about 1:0.2 to about 1:5, from about 1:0.3 to about 1:3, or a combination thereof.

In an embodiment, the first electrode or the second electrode may be a multilayer electrode. In an embodiment, the first electrode (or anode) may be a multilayer electrode including an electrode material in two or more layers, three or more layers, and ten or fewer layers or five or fewer layers. In an embodiment, the second electrode (or cathode) may be a multilayer electrode including an electrode material in two or more layers, three or more layers, and ten or fewer layers or five or fewer layers.

The multilayer electrode may include, for example, a translucent conductive material such as an indium tin oxide, an opaque conductive material such as an aluminum (or a reflective electrode material), or a combination thereof. In an embodiment, the electrode (e.g., an anode or a cathode) may have a structure in which an opaque conductive material (or a reflective electrode material layer) is disposed between translucent conductive materials (e.g., translucent conductive material layers). In an embodiment, the electrode (an anode or a cathode) may have a structure in which a translucent conductive material (e.g., a translucent conductive material layer) is disposed between opaque conductive materials (or reflective electrode materials).

As a voltage is applied between the first electrode and the second electrode, the light emitting layer may emit light upward, downward, or a combination thereof by an electric field, and the light traveling to the reflective electrode may be reflected and emitted in an opposite direction.

In an embodiment, the light may be emitted toward the cathode. In an embodiment, light may be emitted toward the anode.

A thickness of each of the electrodes (the first electrode, the second electrode, or each of the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

The method of forming the electrode is not particularly limited and may be appropriately selected according to the material. In an embodiment, the electrode may be formed by a vapor deposition, a coating, or a combination thereof, but is not limited thereto.

The light emitting layer 3 or 30 disposed between the first electrode 1 and the second electrode 5 (e.g., the anode 10 and the cathode 50) may include a semiconductor nanoparticle (e.g., a blue light emitting nanoparticle, a red light emitting nanoparticle, a green light emitting nanoparticle, or a combination thereof). The light emitting layer may include one or more (e.g., 2 or more or 3 or more and 10 or less) monolayers of a plurality of semiconductor nanoparticles.

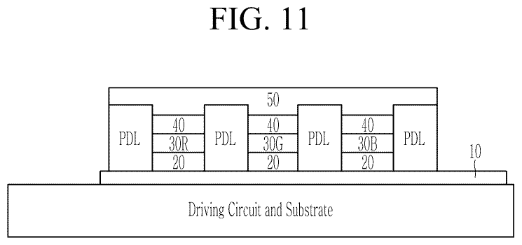

Referring to FIG. 11, the light emitting layer may be patterned. In an embodiment, the patterned light emitting layer may include a blue light emitting layer 30B disposed in the blue pixel, a red light emitting layer 30R disposed in the red pixel, a green light emitting layer 30G disposed in the green pixel, or a combination thereof. Each of the (e.g., red, green, or blue) light emitting layers may be (e.g., optically) separated from an adjacent light emitting layer by a partition wall. In an embodiment, a partition wall such as a black matrix or a pixel defining layer (PDL) may be disposed between the red light emitting layer(s), the green light emitting layer(s), and the blue light emitting layer(s). (See FIG. 4 and FIG. 7) The red light emitting layer, the green light emitting layer, and the blue light emitting layer may be optically isolated from each other.

The emission layer includes a semiconductor nanoparticle. The emission layer or the semiconductor nanoparticles may not include cadmium. The emission layer or the semiconductor nanoparticles may not include mercury, lead, or a combination thereof. The semiconductor nanoparticle may further include or may not include copper, manganese, or a combination thereof. In an embodiment, the semiconductor nanoparticle may include a template crystal and, optionally, may further include a zinc sulfide nanocrystal layer. Details regarding the template crystal, the nanocrystal layer, and the semiconductor nanoparticle are as described herein.

In an embodiment, the semiconductor nanoparticle can form a composition (ink) for an inkjet printing process and can provide a light-emitting layer pattern through the inkjet printing process. A composition for the inkjet process can include the semiconductor nanoparticle of an embodiment and a liquid vehicle. The semiconductor nanoparticle of an embodiment can form a colloidal dispersion in the liquid vehicle. At least a portion of the liquid vehicle can be removed from the light-emitting layer after the inkjet process. The liquid vehicle can include an organic solvent. The organic solvent can include the dispersion solvent described herein. The organic solvent can be an organic solvent having a relatively high boiling point at atmospheric or ambient pressure. The boiling point of the organic solvent or the liquid vehicle can be greater than or equal to about 120° C., greater than or equal to about 130° C., greater than or equal to about 140° C., greater than or equal to about 150° C., greater than or equal to about 160° C., greater than or equal to about 170° C., or greater than or equal to about 180° C. The boiling point of the organic solvent can be less than or equal to about 300° C., less than or equal to about 280° C., less than or equal to about 270° C., less than or equal to about 250° C., or less than or equal to about 200° C. The organic solvent can include a substituted or unsubstituted aromatic solvent such as cyclohexylbenzene, a substituted or unsubstituted C6-C15 aliphatic hydrocarbon solvent such as hexane, octane, or decane, or a combination thereof. When using a mixed solvent, the mixing ratio can be adjusted in consideration of conditions for the inkjet process (e.g., boiling point, viscosity). For example, when using a mixed solvent of an aromatic solvent and an aliphatic solvent, the ratio can be adjusted to 1:0.1 to 1:10, 1:0.3 to 1:3, or 1:0.5 to 1:2 (volume:volume), but is not limited thereto.

The semiconductor nanoparticle may be included in the ink composition by having the properties described herein, contributing to the composition exhibiting an appropriate viscosity. The viscosity may be in the range of about 0.5 centipoise (cPs) to about 30 cPs, about 1 cPs to about 15 cPs, about 1.5 cPs to about 10 cPs, about 2 cPs to about 8 cPs, about 2.5 cPs to about 5 cPs, about 2.8 cPs to about 3.5 cPs, or a combination thereof.

The composition for inkjet printing process may exhibit surface tension or wettability with respect to a common layer, for example, a hole auxiliary layer or an electron auxiliary layer. The surface tension may be in the range of about 10 milliNewtons per meter (mN/m) to about 100 mN/m, about 15 mN/m to about 80 mN/m, about 20 mN/m to about 50 mN/m, about 25 mN/m to about 45 mN/m, about 30 mN/m to about 40 mN/m, about 33 mN/m to about 38 mN/m, or a combination thereof.

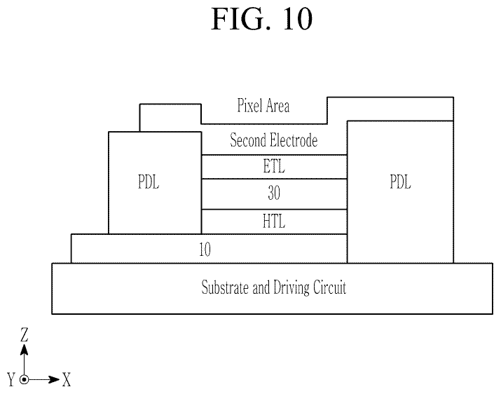

Forming the light-emitting layer by an inkjet printing manner may include putting or accommodating the ink composition containing the semiconductor nanoparticle in equipment equipped with an inkjet printing nozzle, and ejecting/depositing droplets of the composition from the nozzle toward a desired location (e.g., a hole transport layer or electron transport layer surface defined by a partition wall or bank such as a pixel defining layer (PDL)). (See FIG. 10 and FIG. 11)

In an electroluminescent device of an embodiment, a thickness of the light emitting layer may be selected appropriately. In an embodiment, the light emitting layer 3 or 30 may include a monolayer of semiconductor nanoparticles. In an embodiment, the light emitting layer 3 or 30 may include a monolayer of semiconductor nanoparticles, e.g., one or more, two or more, three or more, or four or more and 20 or less, 10 or less, 9 or less, 8 or less, 7 or less, or 6 or less, monolayers of semiconductor nanoparticles. The light emitting layer 3 or 30 may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer 3 or 30 may have a thickness of, for example, about 10 nm to about 150 nm, about 20 nm to about 100 nm, about 30 nm to about 50 nm, or a combination thereof.

The formation of the light emitting layer 3 may be performed by preparing a composition including nanostructures (configured to emit a desired light) and applying or depositing the composition on a substrate, for example, including an electrode or a charge auxiliary layer in, e.g., by, an appropriate method (e.g., spin coating, inkjet printing, and the like).

The forming of the light-emitting layer may further include heat-treating the coated or deposited semiconductor nanoparticle layer. The heat-treating (e.g., thermal treatment, or heat treatment) temperature is not particularly limited, and it can be appropriately selected taking into consideration the boiling point of the organic solvent. For example, the heat treatment temperature may be greater than or equal to about 60° C., or greater than or equal to about 70° C., and less than or equal to about 250° C., or less than or equal to about 180° C. A type of the organic solvent for the coating liquid is not particularly limited and may be selected appropriately. In an embodiment, the organic solvent may include a substituted or unsubstituted aliphatic hydrocarbon organic solvent, a substituted or unsubstituted aromatic hydrocarbon solvent, a substituted or unsubstituted alicyclic hydrocarbon solvent, an acetate solvent, or a combination thereof.

In an embodiment, the light-emitting layer may be a single layer or a multi-layered structure having at least two layers. In the multi-layered structure, adjacent layers (e.g., a first light-emitting layer and a second light-emitting layer) may be configured to emit a first light (e.g., green light, blue light, or red light). In the multi-layered structure, adjacent layers (e.g., a first light-emitting layer and a second light-emitting layer) may have the same or different composition, ligands, or a combination thereof. In an embodiment, the (multi-layered) light-emitting layer may have a halogen amount that varies (increase or decrease) in a thickness direction. In an embodiment, in the (multi-layered) light-emitting layer, the amount of the halogen may increase in a direction toward the electron auxiliary layer. In the (multi-layered) light-emitting layer, an amount, or a content of an organic ligand may decrease in the direction toward the electron auxiliary layer. In the (multi-layered) light-emitting layer, the amount, or the content of the organic ligand may increase in the direction toward the electron auxiliary layer.

The electroluminescent device may include a charge (hole or electron) auxiliary layer between a first electrode and a second electrode (e.g., the first electrode and the second electrode). For example, the electroluminescent display device may include a hole auxiliary layer 20 or an electron auxiliary layer 40 between the first electrode 10 and the emission layer 30 and/or between the second electrode 50 and the emission layer 30. (See FIG. 8 and FIG. 9.)

The light emitting device according to an embodiment may further include a hole auxiliary layer. The hole auxiliary layer 20 is located between the first electrode 10 and the light emitting layer 30. The hole auxiliary layer 20 may include a hole injection layer, a hole transport layer (HTL), an electron blocking layer, or a combination thereof. The hole auxiliary layer 20 may be a layer of a single component or a multilayer structure in which adjacent layers include different components.

The hole auxiliary layer 20 may have a HOMO energy level that can be matched with the HOMO energy level of the light emitting layer 30 in order to enhance mobility of holes transferred from the hole auxiliary layer 20 to the light emitting layer 30. In an embodiment, the hole auxiliary layer 20 may include a hole injection layer close to the first electrode 10 and a hole transport layer close to the light emitting layer 30.

The material included in the hole auxiliary layer 20 (e.g., a hole transport layer, a hole injection layer, or an electron blocking layer) is not particularly limited, and may include, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene): polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-tolylamino)phenyl]cyclohexane (TAPC), a p-type metal oxide (e.g., NiO, WO₃, MoO₃, etc.), a carbon-based material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

The electronic auxiliary layer 40 is located between the light emitting layer 30 and the second electrode 50. The electron auxiliary layer 40 may include, for example, an electron injection layer, an electron transport layer, a hole blocking layer, or a combination thereof. The electron auxiliary layer may include, for example, an electron injection layer (EIL) to facilitate electron injection, an electron transport layer (ETL) to facilitate electron transport, a hole blocking layer (HBL) to inhibit hole transport, or a combination thereof.

In an embodiment, the electron injection layer may be disposed between the electron transport layer and the second electrode. For example, the hole blocking layer may be disposed between the emission layer and the electron transport (injection) layer, but is not limited thereto. A thickness of each layer may be appropriately selected. For example, a thickness of each layer may be greater than or equal to about 1 nm and less than or equal to about 500 nm, but is not limited thereto. The electron injection layer may be an organic layer formed by deposition. The electron transport layer may include an inorganic oxide nanoparticle or may be an organic layer formed by deposition.

The electron transport layer (ETL), electron injection layer (EIL), hole blocking layer, or a combination thereof may include, for example, 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinoline)aluminum (Alq₃), tris(8-hydroxyquinoline)gallium (Gaq₃), tris-(8-hydroxyquinoline)indium (Inq₃), bis(8-hydroxyquinoline)zinc (Znq₂), bis(2-(2-hydroxyphenyl)benzothiazolate)zinc (Zn(BTZ)₂), bis(10-hydroxybenzo[h]quinolinato)beryllium (BeBq₂), 8-(4-(4,6-di(naphthalen-2-yl)-1,3,5-triazin-2-yl)phenyl)quinolone (ET204), 8-hydroxyquinolinato lithium (Liq), n-type metal oxide (e.g., ZnO, HfO₂, etc.), or a combination thereof, but is not limited thereto.

The electron auxiliary layer 40 may include an electron transport layer. The electron transport layer may include a plurality of nanoparticles. The plurality of nanoparticles may include a metal oxide including zinc.

The metal oxide may include zinc oxide, zinc magnesium oxide, or a combination thereof. The metal oxide may include Zn₁₋ₓMₓO (wherein, M is Mg, Ca, Zr, W, Li, Ti, Y, Al, or a combination thereof and 0≤x≤0.5). In an embodiment, M in Zn₁₋ₓMₓO may be magnesium (Mg). In an embodiment, x in Zn₁₋ₓMₓO may be greater than or equal to about 0.01 and less than or equal to about 0.3, for example, less than or equal to about 0.25, less than or equal to about 0.2, or less than or equal to about 0.15.

The absolute value of the LUMO of the above-mentioned nanoparticles included in the emitting layer may be greater or smaller than the absolute value of the LUMO of the metal oxide. The average size of the nanoparticles may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, the thickness of each of the electron auxiliary layers 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the first electrode 10 disposed on the transparent substrate 100 may include a metal oxide-based transparent electrode (e.g., an ITO electrode), and the second electrode (cathode) 50 facing the first electrode 10 may include a conductive metal (e.g., having a relatively low work function, Mg, Al, etc.). The hole auxiliary layer 20 (e.g., a hole injection layer such as PEDOT:PSS, p-type metal oxide, or a combination thereof; a hole transport layer such as TFB, polyvinylcarbazole (PVK), or a combination thereof; or a combination thereof) may be provided between the transparent electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the second electrode 50. (see FIG. 8)

A device according to an embodiment may have an inverted structure. The second electrode 50 disposed on the transparent substrate 100 may include a metal oxide-based transparent electrode (e.g., ITO), and the first electrode 10 facing the second electrode 50 may include a metal (e.g., having a relatively high work function, Au, Ag, etc.). For example, an (optionally doped) n-type metal oxide (crystalline Zn metal oxide) or the like may be disposed as an electron auxiliary layer 40 (e.g., an electron transport layer) between the second electrode 50 and the light emitting layer 30. a hole auxiliary layer 20 (e.g., a hole transport layer including TFB, PVK, or a combination thereof; a hole injection layer including MoO₃ or other p-type metal oxide; or a combination thereof) may be disposed between the first electrode 10 and the light emitting layer 30 (See FIG. 9).

The aforementioned device may be manufactured using an appropriate method. For example, the electroluminescent device may be fabricated by forming a hole auxiliary layer on a substrate with electrodes (e.g., by deposition or coating) as needed, forming an emission layer including nanoparticles (e.g., a pattern of the aforementioned nanoparticles), and forming an electrode (and optionally an electron auxiliary layer) on the emission layer (e.g., by deposition or coating). The formation methods for the electrode, hole auxiliary layer, and electron auxiliary layer may be appropriately selected and are not particularly limited. In an embodiment, each layer included in the hole transport region, the emission layer, and each layer included in the electron transport region may be formed in a predetermined area using various methods such as vacuum deposition, spin coating, casting, Langmuir-Blodgett (LB) method, inkjet printing, laser printing, and laser-induced thermal imaging (LITI). For example, the emission layer may be formed using an inkjet printing method, as described herein.

When each layer included in the hole transport region, the emission layer, and each layer included in the electron transport region is formed by vacuum deposition, the deposition conditions may be appropriately selected. For example, the deposition temperature may range from about 100 to about 500° C., the vacuum level may range from about 10⁻⁸ to about 10⁻³ torr, and the deposition rate may range from about 0.01 to about 100 angstroms per second (Å/sec). The deposition conditions may be selected in consideration of the material included in the layer to be formed and the structure of the layer to be formed.

The electroluminescent device may be configured to emit blue light. The wavelength range of blue light is as described herein. The electroluminescent device may be configured to emit green light. The wavelength range of the green light is as described herein. The electroluminescent device may also be configured to emit red light. The wavelength range of the red light is as described herein.

The electroluminescent device may have a maximum external quantum efficiency of greater than or equal to about 4%, greater than or equal to about 5%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescent device may have a maximum external quantum efficiency of less than or equal to about 50%, less than or equal to about 40%, less than or equal to about 30%, or less than or equal to about 20%.

The electroluminescent device may have a maximum luminance of greater than or equal to about 10,000 nit(cd/m²), greater than or equal to about 20,000 nit, greater than or equal to about 30,000 nit, greater than or equal to about 40,000 nit, greater than or equal to about 50,000 nit, greater than or equal to about 60,000 nit, greater than or equal to about 70,000 nit, greater than or equal to about 80,000 nit, greater than or equal to about 90,000 nit, greater than or equal to about 95,000 nit, greater than or equal to about 100,000 nit, greater than or equal to about 105,000 nit, greater than or equal to about 110,000 nit, greater than or equal to about 115,000 nit, greater than or equal to about 120,000 nit, or greater than or equal to about 125,000 nit. The maximum luminance may be about 3,000 nit to about 500,000 nit.

The electroluminescent device can exhibit improved life-span. In an embodiment, the life-span of the electroluminescent device can be measured while driving at a predetermined initial luminance (e.g., about 146 nit or about 650 nit).

The lifetime T50 of the electroluminescent device may be greater than or equal to about 10 hours, greater than or equal to about 50 hours, greater than or equal to about 80 hours, greater than or equal to about 100 hours, greater than or equal to about 120 hours, greater than or equal to about 130 hours, greater than or equal to about 150 hours, greater than or equal to about 200 hours, greater than or equal to about 250 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, about 600 hours, about 700 hours, about 800 hours, about 900 hours, about 1000 hours, about 1500 hours, or more.

The lifetime T90 of the electroluminescent device may be greater than or equal to about 10 hours, greater than or equal to about 15 hours, greater than or equal to about 20 hours, greater than or equal to about 25 hours, greater than or equal to about 30 hours, greater than or equal to about 35 hours, greater than or equal to about 40 hours, greater than or equal to about 50 hours, greater than or equal to about 75 hours, greater than or equal to about 100 hours, greater than or equal to about 125 hours, greater than or equal to about 150 hours, greater than or equal to about 175 hours, greater than or equal to about 200 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, about 600 hours, about 700 hours, about 800 hours, about 900 hours, about 1000 hours, about 1500 hours, or more.

In an embodiment, T50 may range from about 150 hours to about 5000 hours, about 400 hours to about 4000 hours, about 500 hours to about 3500 hours, about 750 hours to about 2000 hours, about 1000 hours to about 1500 hours, or a combination thereof.

In an embodiment, T90 may range from about 13 hours to about 5000 hours, about 15 hours to about 2800 hours, about 18 hours to about 1200 hours, about 22 hours to about 1000 hours, about 31 hours to about 800 hours, about 50 hours to about 700 hours, about 60 hours to about 500 hours, about 80 hours to about 400 hours, or a combination thereof.

An embodiment relates to a display device (e.g., a display panel) including an electroluminescent device according to an embodiment.

The display device (e.g., a display panel) may include a first pixel and a second pixel configured to emit light of a color different from that of the first pixel. In an embodiment, first light emitted from the emission layer may be extracted through the second electrode (e.g., in the Z direction) (see FIG. 10 or FIG. 11). In an embodiment, the first light may be extracted through a (transparent) first electrode and, optionally, through a substrate 100 (see FIG. 8 or FIG. 9). The emission layer may be disposed within a pixel (or subpixel) in the display device (display panel) as described below (see FIG. 10 or FIG. 11).

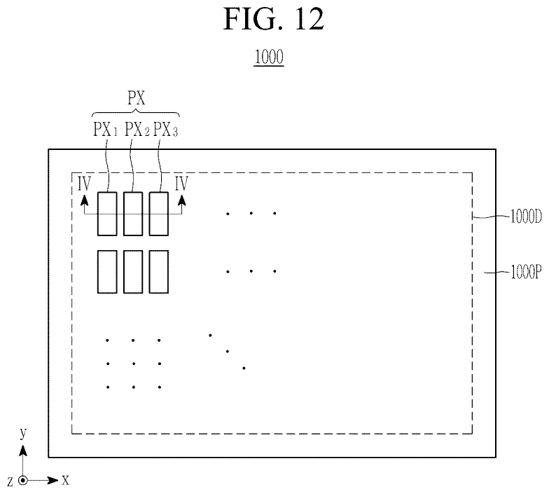

FIG. 11 is a schematic cross-sectional view of a light emitting device (RGB pixel). The light emitting device includes a driving circuit and substrate, a transparent electrode 10, pixel defining layer PDL, a hole auxiliary layer 20, a red light emitting layer 30R, a green light emitting layer 30G, a blue light emitting layer 30B, an electron auxiliary layer 40, and a second electrode 50. Referring to FIG. 12, a display panel 1000 according to an embodiment may include a display area 1000D for displaying an image and, optionally, a non-display area 1000P located around the display area 1000D and having a bonding material disposed thereon.

The display area 1000D may include a plurality of pixels PX arranged along rows (e.g., in the x direction), columns (e.g., in the y direction), or a combination thereof, and each pixel PX may include a plurality of subpixels PX₁, PX₂, and PX₃ that display different colors. As an example, a configuration in which three subpixels PX₁, PX₂, and PX₃ form one pixel is illustrated, but the present disclosure is not limited thereto and may further include additional subpixels such as a white subpixel, or may further include one or more subpixels displaying the same color. The plurality of subpixels PXs may be arranged in, for example, a Bayer matrix, a PenTile matrix, a diamond matrix, or a combination thereof, but is not limited thereto.

Each subpixel PX₁, PX₂, and PX₃ may display a color of three primary colors or a combination of three primary colors, for example, red, green, blue, or a combination thereof. For example, a first subpixel PX₁ may display red, a second subpixel PX₂ may display green, and a third subpixel PX₃ may display blue.

Although the drawing illustrates an example in which all subpixels have the same size, the present disclosure is not limited thereto, and a subpixel, e.g., at least one of the subpixels, may be larger or smaller than the other subpixels. Although the drawing illustrates an example in which all subpixels have the same shape, the present disclosure is not limited thereto, and a subpixel, e.g., at least one of the subpixels, may have a different shape from the other subpixels.

In an embodiment, the display panel may include a light emitting panel 100 including a substrate 110, a buffer layer 111, a thin film transistor (TFT), and a light emitting device 180. The display panel may include circuit elements for switching each light emitting device, driving each light emitting device, or a combination thereof.

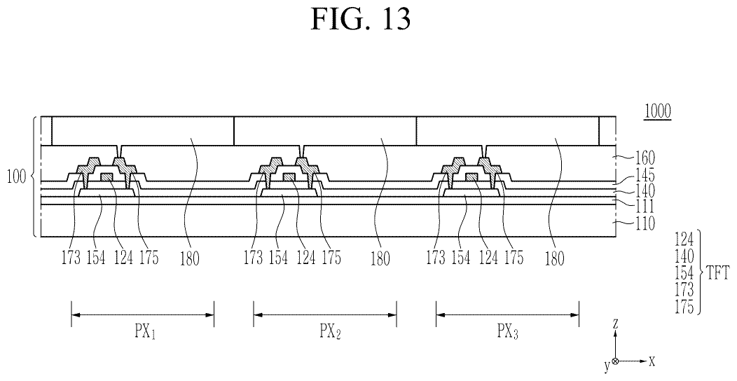

Referring to FIG. 13, in the light emitting panel, light emitting devices 180 may be arranged in each subpixel PX₁, PX₂, and PX₃, and the light emitting devices 180 arranged in the subpixels PX₁, PX₂, and PX₃ may be driven independently. The subpixel may include a blue subpixel, a red subpixel, or a green subpixel. A light emitting device 180, e.g., at least one of the light emitting devices 180, may be an electroluminescent device according to an embodiment.

The substrate 110 is as described above. The buffer layer 111 may include an organic, inorganic, or organic-inorganic material, and may include, for example, an oxide, a nitride or an oxynitride, and may include, for example, silicon oxide, silicon nitride, silicon oxynitride or a combination thereof, but is not limited thereto. The buffer layer 111 may have one layer or two or more layers and may cover the entire surface of the lower substrate 110. The buffer layer 111 may be omitted.

The thin film transistor TFT may be a three-terminal device for switching a light emitting device 180, driving a light emitting device 180, or a combination thereof, and one or more thin film transistors TFT may be included for each subpixel. The thin film transistor TFT includes a gate electrode 124, a semiconductor layer 154 overlapped with the gate electrode 124, a gate insulating film 140 between the gate electrode 124 and the semiconductor layer 154, and a source electrode 173 and a drain electrode 175 electrically connected to the semiconductor layer 154. The drawing shows a coplanar top gate structure as an example, but is not limited thereto and the thin film transistor TFT may have various structures.

The gate electrode 124 is electrically connected to a gate line (not shown) and may include a low-resistance metal such as aluminum (Al), molybdenum (Mo), copper (Cu), titanium (Ti), silver (Ag), gold (Au), alloys thereof, or a combination thereof, but is not limited thereto.

The semiconductor layer 154 may be an inorganic semiconductor such as amorphous silicon, polycrystalline silicon, an oxide semiconductor; an organic semiconductor; an organic-inorganic semiconductor; or a combination thereof. For example, the semiconductor layer 154 may include an oxide semiconductor including indium (In), zinc (Zn), tin (Sn), gallium (Ga), or a combination thereof, and the oxide semiconductor may include, for example, indium-gallium-zinc oxide, zinc-tin oxide, or a combination thereof, but is not limited thereto. The semiconductor layer 154 may include a channel region and a doped region disposed on both sides of the channel region and electrically connected to the source electrode 173 and the drain electrode 175, respectively.

The gate insulating film 140 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The drawing shows an example in which the gate insulating film 140 is formed on the entire surface of the substrate 110, but is not limited thereto and the gate insulating film 140 may be selectively formed between the gate electrode 124 and the semiconductor layer 154. The gate insulating film 140 may have one layer or two or more layers.

The source electrode 173 and the drain electrode 175 may include a low-resistance metal such as aluminum (Al), molybdenum (Mo), copper (Cu), titanium (Ti), silver (Ag), gold (Au), alloys thereof, or a combination thereof, but is not limited thereto. The source electrode 173 and the drain electrode 175 may each be electrically connected to the doping region of the semiconductor layer 154. The source electrode 173 is electrically connected to a data line (not shown), and the drain electrode 175 is electrically connected to a light emitting device 180 described above.

An interlayer insulating film 145 is additionally formed between the gate electrode 124 and the source/drain electrodes 173 and 175. The interlayer insulating film 145 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The interlayer insulating film 145 may have one layer or two or more layers.

In an embodiment, a protective film 160 may be formed on a thin film transistor TFT. The protective film 160 may be, for example, a passivation film, but is not limited thereto. The protective film 160 may include an organic, inorganic, or organic-inorganic material, and may include polyacrylic, polyimide, polyamide, polyamideimide or a combination thereof, but is not limited thereto. The protective film 160 may have one or more layers.

In an embodiment, one of the first electrodes 1 and 10 and the second electrodes 5 and 50 may be a pixel electrode connected to the TFT and the other may be a common electrode.

The electroluminescent device of an embodiment or the display device including the same may be used in a top emission manner, a bottom emission manner, a double-sided emission manner, or a combination thereof.

In an embodiment, the first electrode 10 may be a light transmitting electrode and the second electrode 50 may be a reflective electrode, and the display panel may be a bottom emission type display panel that emits light toward the first electrode 10 and, if present, the substrate 110. In an embodiment, the first electrode 10 may be a reflective electrode and the second electrode 50 may be a light transmitting electrode, and the display panel may be a top emission type display panel that emits light opposite the first electrode 10 and, if present, the substrate 100. In an embodiment, both the first electrode and the second electrode may be light transmitting electrodes, and the display panel 1000 may be a both side emission type display panel that emits light to the substrate 110 side and the opposite side of the substrate 110.

The display device may include a VR/AR device, a portable terminal device, a monitor, a laptop, a television, an electronic board, a camera, or an electrical component (for example, for an automobile).

Hereinafter, specific examples are illustrated. However, these examples are exemplary, and the present disclosure is not limited thereto.

### EXAMPLES

### Analysis Methods

### 1. Photoluminescence

Photoluminescence spectra and absolute quantum yield (QY) of nanoparticles were obtained at room temperature using a Hitachi F-7000 spectrophotometer or a Hamamatsu QY instrument (Quantaurus-QY Absolute PL quantum yield spectrophotometer C11347-11) at an irradiation wavelength of 372 nanometers (nm).

### 2. Transmission Electron Microscope Analysis

Transmission electron microscopy images of the produced nanocrystal particles were obtained using a FEI Titan cubed 60-300 kilovolts (kV) electron microscope.

### 3. HR STEM Analysis

An HR-STEM analysis was performed using an FEI Titan Cubed 60-300 kV transmission electron microscope.

### 4. Inductively Coupled Plasma (ICP) Analysis

Inductively coupled plasma atomic emission spectroscopy (ICP-AES) analysis was performed using a Shimadzu ICPS-8100.

The following synthesis is performed under an inert gas atmosphere (under a nitrogen flowing condition), unless otherwise specified. A precursor amount is a molar content, unless otherwise specified.

### Reference Example 1: Core Preparation

Selenium, sulfur, and tellurium were dispersed in tri-n-octylphosphine (TOP) to obtain a 2 molar (M) Se/TOP stock solution, a 1 M S/TOP stock solution, and a 0.1 M Te/TOP stock solution, respectively.

In a 300 mL reaction flask containing tri-n-octylamine, 4.5 mmol of zinc acetate was added along with oleic acid and heated to 120° C. under vacuum. After 1 hour, the atmosphere in the reactor was switched to an inert gas. The temperature was then raised to 300° C., and the previously prepared Se/TOP stock solution and Te/TOP stock solution were rapidly injected at a Te/Se ratio of 1/30. After the reaction was completed, the reaction solution was rapidly cooled to room temperature, acetone was added, and the resulting precipitate was collected by centrifugation. The precipitate was then dispersed in toluene to obtain a ZnSeTe core. The results of the ICP analysis of the synthesized core are summarized in Table 1.

### Example 1

Selenium, sulfur, and tellurium were each dispersed in trioctylphosphine (TOP) to obtain a 0.45 molar (M) Se/TOP stock solution and a 1M S/TOP solution, respectively. A diluted HF solution was prepared by dissolving hydrofluoric acid (HF) in acetone. In a 300 mL reaction flask containing trioctylamine, zinc acetate was added together with oleic acid, and the mixture was heated to 120° C. under vacuum. After 1 hour, the atmosphere inside the reactor was switched to an inert gas, and the temperature was raised to 280° C. to obtain a zinc oleate precursor (Zn(OA)₂ (TOA solution)).

In another reaction flask containing trioctylamine, 4.8 mmol of zinc acetate, 9.6 mmol of oleic acid, and approximately 0.01 mmol of cesium acetate were added, and the mixture was heated to 120° C. under vacuum. After 1 hour, the atmosphere inside the reactor was switched to an inert gas, and the temperature was raised to 280° C. to obtain a reaction medium containing a zinc precursor and an alkali metal compound (cesium carboxylate) in an organic solvent.

The temperature of the reaction medium was lowered to 220° C., and an 8 mL ZnSeTe core dispersion (Optical Density of the first absorption peak: 0.54 at 383 nm) was injected. A diluted HF solution (10 weight percent (wt %), 0.15 mmol) and a zinc chloride (0.09 mmol) acetone solution were added to the reaction medium. The temperature of the reaction medium was raised to 340° C., followed by two separate additions (A1, A3) of 0.75 mmol of the zinc oleate precursor and 0.6 mmol of the 0.45 M Se/TOP stock solution. The reaction was conducted for 20 minutes to obtain a template crystal.

Subsequently, to form a ZnS-containing nanocrystal layer, 9.6 mmol of Zn(OA)₂ (TOA solution) and 22.4 mmol of 1 M TOP-S were added, and the reaction was carried out for approximately 1.5 hours to form a ZnS nanocrystal layer on the template crystal, yielding a semiconductor nanoparticle.

To recover the template nanocrystal and semiconductor nanoparticle, the reaction solution was cooled to room temperature, ethanol was added, and centrifugation was performed to separate the template crystal and the semiconductor nanoparticle from the reaction solution, respectively. The obtained product was then dispersed in hexane. An ICP analysis was conducted on the template crystal, and the results are summarized in Table 1. Photoluminescence spectroscopy was performed on the obtained semiconductor nanoparticle, confirming that the semiconductor nanoparticle can emit blue light with a peak emission wavelength of 459 nm.

TABLE 1

| | Mole (%) | | |
|---|---|---|---|
| | Zn | Se | Te |
| Reference Example 1 (ZnSeTe) | 53% | 44% | 3% |
| Example 1 (Template crystal) | 55.2% | 44.2% | 0.6% |

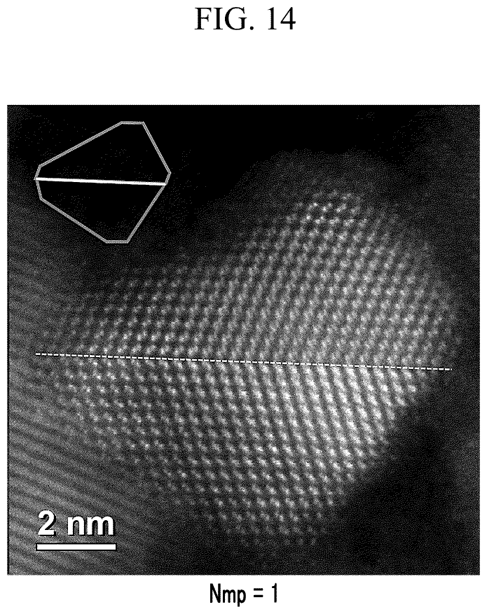

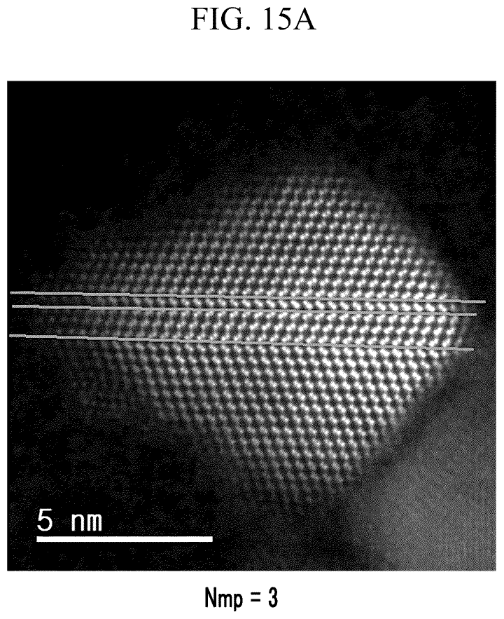

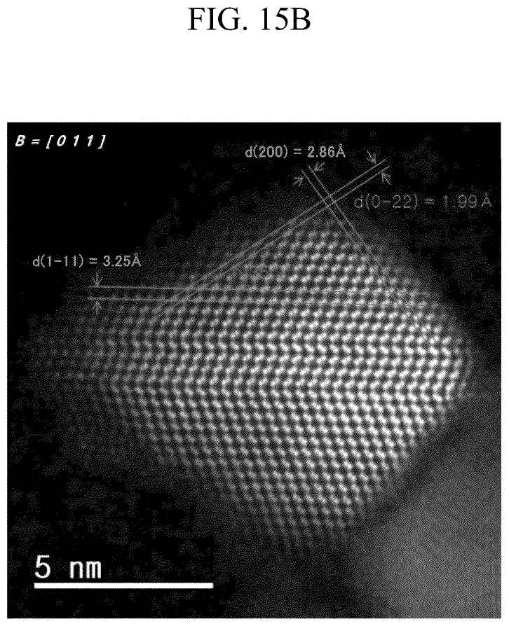

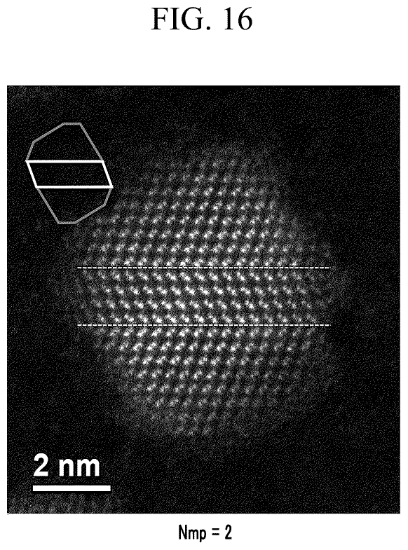

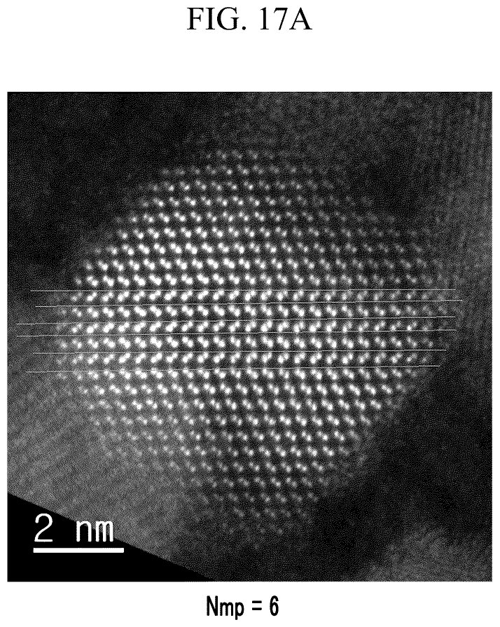

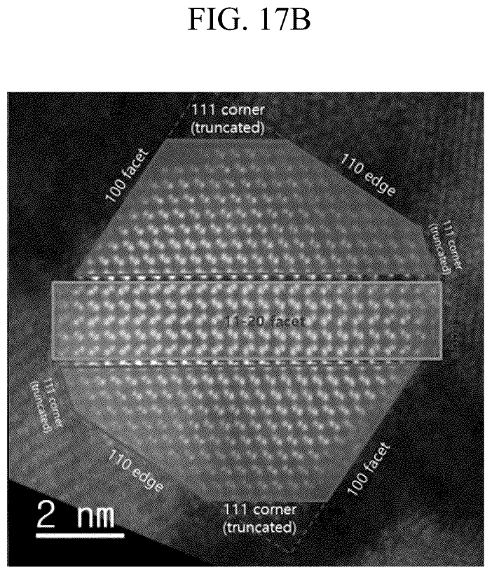

The HR-STEM analysis was performed on the obtained template crystals, and the results are shown in FIG. 14, FIG. 15A, FIG. 15B, FIG. 16, FIG. 17A, and FIG. 17B.

The template crystal shown in FIG. 14 exhibits a triangular pyramid shape, where a single mirror plane is present, and a first region and a second region, each having a pyramidal shape, are arranged above and below the mirror plane. It can be observed that the atomic arrangement direction (first direction) of zinc and chalcogen elements in the bilayers of the first region is mirror-symmetric (reflection symmetric) to the atomic arrangement direction (second direction) of zinc and chalcogen elements in the bilayers of the second region across the mirror plane.

The template crystal shown in FIG. 15A and FIG. 15B includes a mirror region with three mirror planes and exhibits a triangular pyramid shape, where a first region and a second region, each having a pyramidal shape, are arranged above and below the mirror region. It can be observed that the atomic arrangement direction (first direction) of zinc and chalcogen elements in the bilayers of the first region and the atomic arrangement direction (second direction) of zinc and chalcogen elements in the bilayers of the second region are in a reflection symmetric relationship. FIG. 15B further illustrates the measurement results of the d-spacing between bilayers. The d-spacing between adjacent layers of the zinc-chalcogen element bilayers in the <111> direction according to embodiments may be greater than or equal to about 1 Å and less than or equal to about 4 Å. It was confirmed that the d-spacing between the {111} bilayers is approximately 3.3 Å.

The template crystal shown in FIG. 16 includes a mirror region with two mirror planes and exhibits a cubic-like pyramidal shape, where a first region and a second region, each having a pyramidal shape, are arranged above and below the mirror region. It can be observed that the atomic arrangement direction (first direction) of zinc and chalcogen elements in the bilayers of the first region and the atomic arrangement direction (second direction) of zinc and chalcogen elements in the bilayers of the second region are parallel (e.g., identical).

The template crystal shown in FIG. 17A and FIG. 17B includes a mirror region with six mirror planes and exhibits a cubic-like pyramidal shape, where a first region and a second region, each having a pyramidal shape, are arranged above and below the mirror region. It can be observed that the atomic arrangement direction (first direction) of zinc and chalcogen elements in the bilayers of the first region and the atomic arrangement direction (second direction) of zinc and chalcogen elements in the bilayers of the second region are parallel (e.g., identical).

The correlation between the shape and the number of mirror planes was also confirmed. It was confirmed that, in a template crystal including an odd number of mirror planes and a semiconductor nanoparticle including the same, the growth direction was induced to exhibit reflection symmetry, forming a right-triangular bipyramidal structure (FIG. 15A and FIG. 2C). In contrast, in a template crystal including an even number of mirror planes and a semiconductor nanoparticle including the same, the growth direction was induced to be identical (or parallel), forming a cubic-like bipyramidal structure (FIG. 17A and FIG. 2D).

### Experimental Example 1

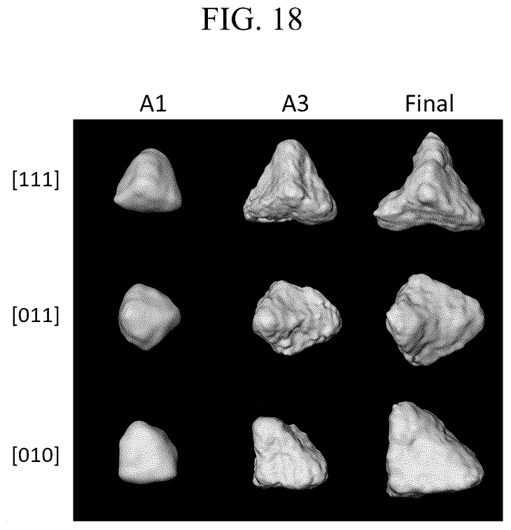

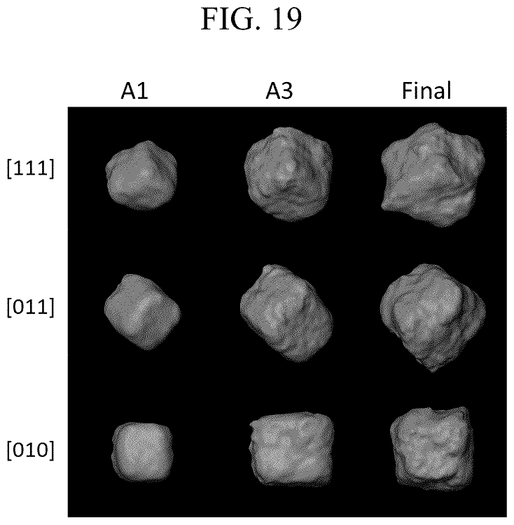

For the template crystal and semiconductor nanoparticle synthesized in Example 1, three-dimensional tomographic image analysis was conducted to visualize them, and the results were summarized in FIG. 18 and FIG. 19. It was confirmed that the template crystal and semiconductor nanoparticles synthesized in Example 1 were accurately characterized as right-triangular bipyramidal and cubic-shaped bipyramidal structures (FIG. 18 and FIG. 19).

### Example 2

A semiconductor nanoparticle was synthesized in the same manner as in Example 1, except that the amount of cesium acetate was increased to 0.06 mmol. It was confirmed that most of the synthesized semiconductor nanoparticles formed a cubic-like bipyramidal structure.

Photoluminescence spectroscopy analysis was performed on the synthesized semiconductor nanoparticle. As a result, it was confirmed that the synthesized semiconductor nanoparticles emitted blue light (emission peak wavelength: 467 nm).

### Comparative Example 1

A template crystal and semiconductor nanoparticles were prepared in the same manner as in Example 1, except that cesium acetate was not used.

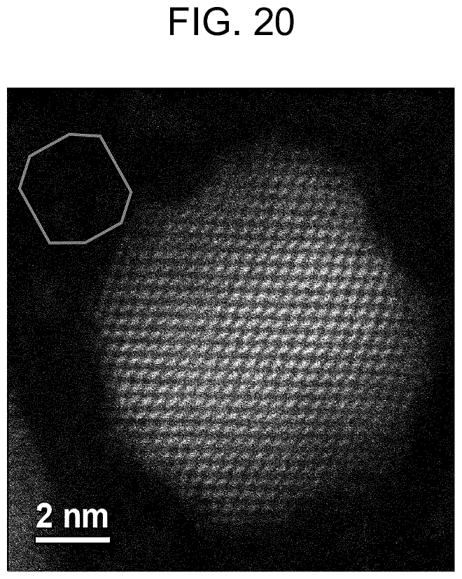

A HR-TEM analysis was performed on the prepared template crystal, and the results are shown in FIG. 20. From the results in FIG. 20, it was confirmed that the prepared template crystal did not include mirror planes.

### Experimental Example 2

A TEM analysis was performed on the template crystals prepared in Example 1, Example 2, and Comparative Example 1, and the results were summarized in Table 2.

TABLE 2

| | Average size and standard deviation | Circularity |
|---|---|---|
| Example 1 | 10.6 nm ± 1.8 | 0.71 ± 0.05 |
| Example 2 | 17.8 nm ± 2.5 | 0.75 ± 0.05 |
| Comp. Example 1 | 8.5 nm ± 1.2 | 0.84 ± 0.05 |

From the results in Table 2, it was confirmed that the template crystals of the examples had different sizes and circularities compared to Comparative Example 1.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims

What is claimed is:

1. A semiconductor nanoparticle,
wherein the semiconductor nanoparticle comprises a template crystal comprising a zinc chalcogenide and does not comprise cadmium,
wherein the template crystal comprises zinc-chalcogen bilayers stacked in a [111] direction,
wherein, as observed using a scanning transmission electron microscopy, the template crystal comprises a first zone, a second zone, and a mirror zone disposed between the first zone and the second zone,
wherein the mirror zone comprises at least one mirror plane at which a reversal occurs in an atomic arrangement direction of zinc and a chalcogen element between adjacent layers of the zinc-chalcogen bilayers,
wherein, in the zinc-chalcogen bilayers of the first zone, zinc atoms and chalcogen element atoms are arranged in a first direction,
wherein, in the zinc-chalcogen bilayers of the second zone, zinc atoms and chalcogen element atoms are arranged in a second direction,
wherein the first direction is symmetric with or parallel to the second direction,
wherein, in at least a portion of the first zone, lengths of the zinc-chalcogen bilayers decrease as being away from the mirror zone,
wherein, in at least a portion of the second zone, lengths of the zinc-chalcogen bilayers decrease as being away from the mirror zone, and
wherein the mirror zone has a thickness that is less than or equal to about 50% of the total height of the template crystal.

2. The semiconductor nanoparticle of claim 1, wherein the zinc chalcogenide comprises zinc and selenium, and the chalcogen element is selenium, and optionally tellurium.

3. The semiconductor nanoparticle of claim 1, wherein
the first zone and the second zone each have a shape of a pyramid, and, optionally, the shape of the pyramid is truncated at an edge.

4. The semiconductor nanoparticle of claim 1, wherein
a number of the mirror planes in the mirror zone is greater than or equal to about 1 and less than or equal to about 10.

5. The semiconductor nanoparticle of claim 1, wherein
a number of the mirror planes in the mirror zone is an odd number, and the first direction and the second direction are symmetric to each other.

6. The semiconductor nanoparticle of claim 1,
wherein a number of the mirror planes in the mirror zone is an even number, and the first direction and the second direction are parallel to each other.

7. The semiconductor nanoparticle of claim 1,
wherein the template crystal comprises a plurality of {100} crystal facets, a number of which is greater than or equal to about 4.

8. The semiconductor nanoparticle of claim 1,
wherein, in the first zone or the second zone, a d-spacing between adjacent layers of the zinc-chalcogen bilayers in the <111> direction is greater than or equal to about 1 angstrom and less than or equal to about 4 angstrom.

9. The semiconductor nanoparticle of claim 1,
wherein a total height of the template crystal is greater than or equal to about 5 nanometers and less than or equal to about 45 nanometers.

10. The semiconductor nanoparticle of claim 1,
wherein a number of the zinc-chalcogen bilayers in the first zone is greater than or equal to about 3 and less than or equal to about 20, and
wherein a number of the zinc-chalcogen bilayers in the second zone is greater than or equal to about 3 and less than or equal to about 20.

11. The semiconductor nanoparticle of claim 1,
wherein the mirror zone comprises a single mirror plane, or
wherein the mirror zone has a thickness of greater than or equal to about 0.3 nanometer and less than or equal to about 10 nanometers.

12. The semiconductor nanoparticle of claim 1,
wherein the mirror zone has a length greater than or equal to about 3 nanometers and less than or equal to about 80 nanometers.

13. The semiconductor nanoparticle of claim 1,
wherein the template crystal has a shape of a trigonal bipyramid or a cube-like bipyramid.

14. The semiconductor nanoparticle of claim 1,
wherein the template crystal further comprises tellurium, and
wherein, in the template crystal, a mole ratio of selenium to zinc is from about 0.5:1 to about 1.5:1.

15. The semiconductor nanoparticle of claim 14,
wherein, in the template crystal, a mole ratio of tellurium to selenium is greater than or equal to about 0.0001:1 and less than or equal to about 0.05:1.

16. The semiconductor nanoparticle of claim 1,
wherein the semiconductor nanoparticle is disposed on the template crystal and further comprises a nanocrystal layer, and
wherein the nanocrystal layer comprises zinc and sulfur.

17. The semiconductor nanoparticle of claim 1,
wherein the semiconductor nanoparticle has a size of greater than or equal to about 8 nanometers and less than or equal to about 50 nanometers, and
wherein the semiconductor nanoparticle is configured to emit blue light.

18. A method for producing the semiconductor nanoparticle of claim 1, comprising:
obtaining a core including a first zinc chalcogenide; and
reacting a zinc precursor and a chalcogen element in a reaction medium including an organic solvent in the presence of the core,
wherein the reaction medium further comprises a fluorine compound and an alkali metal compound.

19. The method of claim 18,
wherein the fluorine compound is hydrofluoric acid, and the alkali metal compound comprises a cesium carboxylate, a rubidium carboxylate, or a combination thereof; or
wherein an amount of the alkali metal compound in the reaction medium is greater than or equal to about 0.01 molar percent and less than or equal to about 5 molar percent relative to the zinc precursor; or
wherein the fluorine compound is hydrofluoric acid, and the alkali metal compound comprises a cesium carboxylate, a rubidium carboxylate, or a combination thereof, and an amount of the alkali metal compound in the reaction medium is greater than or equal to 0.01 molar percent and less than or equal to 5 molar percent relative to the zinc precursor.

20. A light-emitting device comprising a hole transport layer, an electron transport layer, and an emission layer disposed between the hole transport layer and the electron transport layer,
wherein the emission layer comprises the semiconductor nanoparticle of claim 1.
